(19) United States
(12) Patent Application Publication
(10) Pub. No.: US 2025/0197698 A1
(43) Pub. Date: Jun. 19, 2025

(54) ADHESIVE SHEET, ADHESIVE SHEET WITH RELEASE FILM USING SAME, LAMINATE FOR IMAGE DISPLAY DEVICE, FLEXIBLE IMAGE DISPLAY DEVICE, ADHESIVE SHEET FOR CONSTITUENT MEMBER OF FLEXIBLE IMAGE DISPLAY DEVICE, AND ADHESIVE COMPOSITION

(71) Applicant: MITSUBISHI CHEMICAL CORPORATION, Tokyo (JP)

(72) Inventor: Masaya MINEMOTO, Tokyo (JP)

(73) Assignee: MITSUBISHI CHEMICAL CORPORATION, Tokyo (JP)

(21) Appl. No.: 19/070,194

(22) Filed: Mar. 4, 2025

Related U.S. Application Data
(63) Continuation of application No. PCT/JP2023/037195, filed on Oct. 13, 2023.

(30) Foreign Application Priority Data
Nov. 15, 2022 (JP) 2022-182790

(51) Int. Cl. C09J 133/08; C09J 7/40

(52) U.S. Cl. CPC C09J 133/08; C09J 7/40

(57) ABSTRACT

Provided as an adhesive sheet having a low refractive index and excellent flexibleness is the following.

An adhesive sheet formed with an adhesive composition including an acrylic copolymer and a radically polymerizable compound (x), wherein
the adhesive sheet has a refractive index of not greater than 1.470, and
the adhesive sheet has a shear storage elastic modulus ratio (G′(−30° C.)/G′ (80° C.)) of 1 to 65. The ratio is between a shear storage elastic modulus at −30° C. (G′(−30° C.)) and a shear storage elastic modulus at 80° C. (G′(80° C.)), and obtained by dynamic viscoelasticity measurement with a shear mode at a frequency of 1 Hz.

### RELATED APPLICATIONS

This application is a continuation of International Application No. PCT/JP2023/037195, filed on Oct. 13, 2023, which claims priority to Japanese Patent Application No. 2022-182790, filed on Nov. 15, 2022, the entire contents of each of which are herein incorporated by reference.

### TECHNICAL FIELD

The present disclosure relates to an adhesive sheet, an adhesive sheet with a release film using the same, a laminate for an image display device, a flexible image display device, an adhesive sheet for a constituent member of a flexible image display device, and an adhesive composition. The present disclosure further particularly relates to an adhesive sheet having a low refractive index and having flexibleness, an adhesive sheet with a release film using the same, a laminate for an image display device, a flexible image display device, an adhesive sheet for a constituent member of a flexible image display device, and an adhesive composition.

### BACKGROUND ART

Flexible image display devices using an organic light-emitting diode (OLED) and a quantum dot (QD) have been developed and commercially used widely in recent years.

The flexible image display devices include a bendable device having an image device surface having a curved shape, a foldable device that can be repeatedly folded, a rollable device that can be wound, and a stretchable device that is stretched.

Such image display devices have laminate structures in which a plurality of member sheets such as a surface-protective film, a cover lens, a circularly polarizing plate, a touch film sensor, and a light-emitting element are laminated with a transparent adhesive sheet, and each of the laminate structures can be regarded as a laminated sheet in which the member sheet and the adhesive sheet are laminated.

The foldable and bendable image display device has various problems caused by interlayer stress when folded. For example, required is a laminated sheet in which an effect by placing in a bent state does not remain and in which the state is rapidly recovered to a flat state when the display is opened from a folded state.

In addition, repeating the folding operations peels the adhesive sheet or applies stress to the member being adherends to cause cracking of the member, finally leading to breakage. In particular, a laminated sheet durable for repeating folding operations at low temperature, which is a severer condition, is also required.

Furthermore, the laminated sheet has been required to have, in addition to the durability at low temperature, a higher elastic modulus from the viewpoints of inhibiting glue ooze of the adhesive sheet itself, inhibiting folding trace due to deformation of the adhesive sheet in folding at high temperature, etc.

The adhesive sheet in such a flexible image display device is required to have optical properties of course, and flexibleness, specifically high durability against folding.

For example, PTL 1 discloses a laminated film with an adhesive layer causing no risk of image disturbance displayed on a folded part after repeated folding.

PTL 2 discloses a laminate containing a double-sided adhesive sheet having a glass transition temperature and storage elastic modulus within predetermined ranges and a flexible member for an image display device that does not cause folding and peeling even in a bending test close to an actual use environment. The laminate does not cause folding and peeling even in a bending test closely under the practical use conditions.

Further, such laminated sheets have problems of light scattering on an interface between the adhesive sheet and a member sheet caused by a difference in a refractive index of the adhesive sheet and the member sheet to decrease light transmittance of the laminated sheet or to cause unevenness of the displayed image. Such problems become furthermore considerable when the member sheet has roughness on the surface or in a bending part in the flexible image display device. Thus, to reduce the difference in the refractive index of the adhesive sheet and the member sheet, a demand of an adhesive sheet having a low refractive index has increased.

For example, PTL 3 discloses an adhesive containing an acrylic polymer having a fluorine-containing acrylic monomer (M1) as a monomer unit, wherein a refractive index is not greater than 1.46.

### RELATED ART DOCUMENT

### Patent Document

PTL 1: JP-A-2020-196255
PTL 2: WO-A-2018/173896
PTL 3: JP-A-2022-008016

### SUMMARY

### Problems to be Solved by the Disclosure

However, the art disclosed in PTL 1 and 2 considers durability in folding but does not consider the refractive index of the adhesive sheet.

PTL 3 provides the adhesive sheet having a low refractive index but does not consider flexibleness required in recent years, and further improvement for achievement of both the flexibleness and the low refractive index has been required.

Accordingly, under such background, the present disclosure provides an adhesive sheet having a low refractive index and having flexibleness, an adhesive sheet with a release film using the same, a flexible image display device, an adhesive sheet for a constituent member of a flexible image display device, and an adhesive composition.

### Means for Solving the Problems

Whereas, in view of the above circumstances, the present inventors have found that the adhesive sheet having a low refractive index and excellent flexibleness can be obtained by using a specific amount of a radically polymerizable compound in which a refractive index of a monomer is lower than a refractive index of an acrylic copolymer, etc.

Blending a larger amount of a radically polymerizable compound having a low refractive index with an acrylic copolymer, specifically an acrylic copolymer suitable for the flexible image display device (or blending to form an adhesive sheet), is typically considered to cause phase separation to cause defects such as deterioration of optical properties due to insufficient compatibility. However, the present disclosure surprisingly does not cause such defects to provide excellent flexibleness while having the low refractive index, and has achieved the object of the present disclosure.

Specifically, the present disclosure has the following aspects.
[1] An adhesive sheet formed with an adhesive composition including an acrylic copolymer and a radically polymerizable compound (x), wherein
   the adhesive sheet has a refractive index of not greater than 1.470, and
   the adhesive sheet has a shear storage elastic modulus ratio (G′(−30° C.)/G′ (80° C.)) of 1 to 65, the ratio being between a shear storage elastic modulus at −30° C. (G′(−30° C.)) and a shear storage elastic modulus at 80° C. (G′(80° C.)), and being obtained by dynamic viscoelasticity measurement with a shear mode at a frequency of 1 Hz.
[2] The adhesive sheet according to [1], wherein the adhesive sheet has a content of the radically polymerizable compound (x) of 20 to 95% in a total mass of the adhesive composition.
[3] The adhesive sheet according to [1] or [2], wherein the acrylic copolymer is an acrylic copolymer having: a structural moiety derived from a (meth)acrylate (a1) having an alkyl group having not less than 3 carbon atoms of the alkyl; and a structural moiety derived from a hydroxy-group-containing (meth)acrylate (a2).
[4] The adhesive sheet according to any one of [1] to [3], wherein the acrylic copolymer has a weight-average molecular weight of not less than 500,000.
[5] An adhesive sheet, including an acrylic adhesive layer, wherein the acrylic adhesive layer is a cured reaction product formed with a syrup composition including: an alkyl(meth)acrylate (a1) having not less than 3 carbon atoms of the alkyl group; a hydroxy-group-containing (meth)acrylate (a2); and a radically polymerizable compound (x),
   the adhesive sheet has a refractive index of not greater than 1.470, and
   the adhesive sheet has a shear storage elastic modulus ratio (G′(−30° C.)/G′ (80° C.)) of 1 to 65, the ratio being between a shear storage elastic modulus at −30° C. (G′(−30° C.)) and a shear storage elastic modulus at 80° C. (G′(80° C.)), and being obtained by dynamic viscoelasticity measurement with a shear mode at a frequency of 1 Hz.
[6] The adhesive sheet according to [5], wherein the adhesive sheet has a content of a structural moiety derived from the radically polymerizable compound (x) of 20 to 95% in a total mass of the acrylic adhesive layer.
[7] The adhesive sheet according to any one of [1] to [6], wherein the radically polymerizable compound (x) has a refractive index of less than 1.46.
[8] The adhesive sheet according to any one of [1] to [7], wherein the radically polymerizable compound (x) has an alkylene glycol skeleton.
[9] The adhesive sheet according to any one of [1] to [8], wherein the radically polymerizable compound (x) has a urethane bond.
[10] The adhesive sheet according to any one of [1] to [9], wherein the shear storage elastic modulus at −30° C. (G′(−30° C.)) obtained by the dynamic viscoelasticity measurement with a shear mode at a frequency of 1 Hz is not greater than 1000 kPa.
[11] The adhesive sheet according to any one of [1] to [10], wherein the shear storage elastic modulus at 80° C. (G′(80° C.)) obtained by the dynamic viscoelasticity measurement with a shear mode at a frequency of 1 Hz is not less than 1 kPa.
[12] The adhesive sheet according to any one of [1] to [11], wherein the adhesive sheet has a glass transition temperature (Tg) of not higher than −20° C., the glass transition temperature being defined by a maximum value of Tan δ obtained with the dynamic viscoelasticity measurement with a shear mode at a frequency of 1 Hz.
[13] The adhesive sheet according to any one of [1] to [12], wherein the adhesive sheet has a recovering rate of not less than 80%, the recovering rate being calculated with a following formula from a strain (γₘₐₓ) after applying a pressure of 10 kPa for 600 seconds with a thickness of 0.5 to 1.2 mm at a temperature of 25° C. and a strain (γₘᵢₙ) after 600 seconds from subsequently removing a stress of the pressure,

$$the recovering rate ( \% ) = [ ( {γ}_{max} - {γ}_{min} ) / {γ}_{max} ] \times 100$$

[14] The adhesive sheet according to any one of [1] to [13], wherein the adhesive sheet has a gel fraction of 30 to 95 mass %.
[15] An adhesive sheet with a release film, including:
   the adhesive sheet according to any one of [1] to [14]; and
   a release film laminated onto the adhesive sheet.
[16] A laminate for an image display device, including:
   two constituent members of an image display device; and
   the adhesive sheet according to any one of [1] to interposed between the two constituent members of an image display device.
[17] A flexible image display device, including the laminate for an image display device according to [16].
[18] An adhesive sheet for a constituent member of a flexible image display device, the adhesive sheet including the adhesive sheet according to any one of [1] to [14].
[19] An adhesive composition, including:
   an acrylic copolymer; and
   a radically polymerizable compound (x), wherein
   the acrylic copolymer has a weight-average molecular weight of not less than 500,000,
   the radically polymerizable compound (x) has a refractive index of less than 1.46, and
   the adhesive composition has a content of the radically polymerizable compound (x) of 20 to 95% in a total mass of the adhesive composition.

### Effects of the Disclosure

The adhesive sheet of the present disclosure has a low refractive index and excellent flexibleness. Therefore, the adhesive sheet of the present disclosure can be suitably used as an adhesive sheet used for a flexible image display device.

### EMBODIMENTS OF THE DISCLOSURE

Hereinafter, an example of embodiments of the present disclosure will be described in detail. Note that the present disclosure is not limited to the embodiments described below.

In the present disclosure, “film” conceptually encompasses sheets, films, and tapes.

The expression “panel” as used in “image display panel,” “protection panel,” etc., encompasses plates, sheets, and films.

In the present disclosure, the description “x to y,” wherein x and y are given numbers, encompasses meanings of “preferably greater than x” and “preferably less than y” unless otherwise specified, in addition to a meaning of “not less than x and not greater than y.”

The description “not less than x,” wherein x is a given number, encompasses a meaning of “preferably greater than x” unless otherwise specified. The description “not greater than y,” wherein y is a given number, encompasses “preferably less than y” unless otherwise specified.

Further, the expression “x and/or y,” wherein x and y are each a given configuration, means at least one of x and y, and means the following three meanings: only x; only y; and x and y.

In the present disclosure, the term “(meth)acryl” means to encompass “acryl” and “methacryl,” the term “(meth)acrylate” means to encompass “acrylate” and “methacrylate,” and the term “(meth)acryloyl” means to encompass “acryloyl” and “methacryloyl.”

### <<Adhesive Sheet>>

An adhesive sheet according to an example of the first embodiment of the present disclosure (hereinafter, referred to as “the present adhesive sheet 1”) is formed with an adhesive composition containing an acrylic copolymer and a radically polymerizable compound (x). The adhesive sheet has a refractive index of not greater than 1.470. The adhesive sheet has a shear storage elastic modulus ratio (G′(−30° C.)/G′ (80° C.)) of 1 to 65. The ratio is between a shear storage elastic modulus at −30° C. (G′(−30° C.)) and a shear storage elastic modulus at 80° C. (G′(80° C.)), and is obtained by dynamic viscoelasticity measurement with a shear mode at a frequency of 1 Hz.

An adhesive sheet according to an example of the second embodiment of the present disclosure (hereinafter, referred to as “the present adhesive sheet 2”) is an adhesive sheet having an acrylic adhesive layer. The acrylic adhesive layer is a cured reaction product formed with a syrup composition containing: an alkyl(meth)acrylate (a1) having not less than 3 carbon atoms of the alkyl group [hereinafter, referred to as “alkyl(meth)acrylate (a1)”]; a hydroxy-group-containing (meth)acrylate (a2); and a radically polymerizable compound (x). The adhesive sheet has a refractive index of not greater than 1.470. The adhesive sheet has a shear storage elastic modulus ratio (G′(−30° C.)/G′ (80° C.)) of 1 to 65. The ratio is between a shear storage elastic modulus at −30° C. (G′(−30° C.)) and a shear storage elastic modulus at 80° C. (G′(80° C.)), and is obtained by dynamic viscoelasticity measurement with a shear mode at a frequency of 1 Hz.

Hereinafter, the present adhesive sheet 1 and the present adhesive sheet 2 will be described.

### <The Present Adhesive Sheet 1>

The present adhesive sheet 1 is formed with an adhesive composition containing an acrylic copolymer and a radically polymerizable compound (x).

Hereinafter, each component contained in the adhesive composition will be described in detail.

### Acrylic Copolymer

The acrylic copolymer used in the present adhesive sheet 1 is preferably an acrylic copolymer having a structural moiety derived from an alkyl(meth)acrylate and a structural moiety derived from a hydroxy-group-containing (meth)acrylate. Particularly, the acrylic copolymer is preferably an acrylic copolymer having a structural moiety derived from an alkyl(meth)acrylate (a1) having not less than 3 carbon atoms of the alkyl group and a structural moiety derived from a hydroxy-group-containing (meth)acrylate (a2) in terms of adhesive properties. Such an acrylic copolymer is obtained by polymerizing copolymerization components containing the alkyl(meth)acrylate (a1) having not less than 3 carbon atoms of the alkyl group and the hydroxy-group-containing (meth)acrylate (a2).

The copolymerization components may contain components other than the (meth)acrylate (a1) having not less than 3 carbon atoms of the alkyl group and the hydroxy-group-containing (meth)acrylate (a2). Examples of the other components include: at least one copolymerizable monomer (a3) selected from an alkyl(meth)acrylate having 1 or 2 carbon atoms of the alkyl group and a vinyl ester monomer [hereinafter, referred to as “copolymerizable monomer (a3)”; a functional-group-containing ethylenically unsaturated monomer (a4); and another copolymerizable monomer (a5).

### Alkyl (Meth)acrylate (a1)

Examples of the alkyl(meth)acrylate (a1) include aliphatic (meth)acrylates such as linear alkyl(meth)acrylates, branched alkyl (meth)acrylates, and alicyclic (meth)acrylates.

Examples of the aliphatic (meth)acrylates include: linear alkyl(meth)acrylates such as n-propyl (meth)acrylate, n-butyl (meth)acrylate, n-pentyl (meth)acrylate, n-hexyl (meth)acrylate, n-heptyl (meth)acrylate, n-octyl (meth)acrylate, n-nonyl (meth)acrylate, n-decyl (meth)acrylate, lauryl (meth)acrylate, n-tridecyl (meth)acrylate, stearyl (meth)acrylate, icosyl (meth)acrylate, henicosyl (meth)acrylate, and behenyl (meth)acrylate; and branched alkyl(meth)acrylates such as isopropyl (meth)acrylate, isobutyl(meth)acrylate, sec-butyl (meth)acrylate, t-butyl(meth)acrylate, isopentyl (meth)acrylate, neopentyl (meth)acrylate, 2-ethylhexyl (meth)acrylate, isooctyl (meth)acrylate, isononyl (meth)acrylate, isodecyl (meth)acrylate, isostearyl (meth)acrylate, and isoicosyl (meth)acrylate.

Examples of the alicyclic (meth)acrylates include alicyclic (meth)acrylates such as cyclohexyl (meth)acrylate, t-butylcyclohexyl (meth)acrylate, isobornyl (meth)acrylate, 3,3,5-trimethylcyclohexyl (meth)acrylate, and adamantyl (meth)acrylate.

These may be used singly or in combination of two or more thereof.

Among these, the linear alkyl(meth)acrylates are preferable in terms of adhesiveness and recovering properties. From the viewpoint of balance between the adhesiveness and bendability at low temperature, linear or branched alkyl(meth)acrylates having 3 to 18, further 3 to 16, particularly 3 to 12, and still particularly 3 to 8, carbon atoms of the alkyl group are preferable. Examples thereof include n-propyl (meth)acrylate, n-butyl(meth)acrylate, n-pentyl (meth)acrylate, n-hexyl (meth)acrylate, n-octyl (meth)acrylate, n-nonyl (meth)acrylate, decyl (meth)acrylate, and 2-ethylhexyl (meth)acrylate. Among these, n-butyl(meth)acrylate and 2-ethylhexyl (meth)acrylate are preferable.

From the viewpoint of reducing the refractive index, alkyl (meth)acrylates having not less than 4, particularly not less than 6, still particularly not less than 8, not greater than 18, particularly not greater than 16, and still particularly not greater than 12, carbon atoms of the alkyl group are preferable.

From the viewpoint of inhibiting increase in the shear storage elastic modulus (G′) at low temperature to improve bendability, the alkyl(meth)acrylate (a1) is particularly preferably an acrylate.

A content of the structural moiety derived from the alkyl (meth)acrylate (a1) relative to the acrylic copolymer is typically 40 to 95%, preferably 45 to 90%, and particularly preferably 50 to 85 mass % in the total mass of the acrylic copolymer in terms of inhibiting increase in the shear storage elastic modulus (G′) at low temperature. The content of the structural moiety derived from the alkyl(meth)acrylate (a1) of not lower than the above lower limit is preferable in terms of inhibiting increase in the shear storage elastic modulus (G′) at low temperature, and the content of not greater than the above upper limit is preferable in terms of achievement of both adhesiveness etc. and other physical properties.

### Hydroxy-Group-Containing (Meth)acrylate (a2)

Examples of the hydroxy-group-containing (meth)acrylate (a2) include: hydroxyalkyl(meth)acrylates such as 2-hydroxyethyl (meth)acrylate, 4-hydroxybutyl(meth)acrylate, 5-hydroxypentyl (meth)acrylate, 6-hydroxyhexyl (meth)acrylate, and 8-hydroxyoctyl (meth)acrylate; caprolactone-modified hydroxy (meth)acrylates such as caprolactone-modified 2-hydroxyethyl(meth)acrylate; (meth)acrylates having an oxyalkylene glycol structure such as diethylene glycol (meth)acrylate, polyethylene glycol (meth)acrylate, polypropylene glycol (meth)acrylate, polytetramethylene glycol (meth)acrylate, and polyoxyethylene polyoxypropylene glycol (meth)acrylate; primary-hydroxy-group-containing (meth)acrylates such as 2-acryloyloxyethyl 2-hydroxyethylphthalate; secondary-hydroxy-group-containing (meth)acrylates such as 2-hydroxypropyl (meth)acrylate, 2-hydroxybutyl(meth)acrylate, and 3-chloro-2-hydroxypropyl (meth)acrylate; and tertiary-hydroxy-group-containing (meth)acrylates such as 2,2-dimethyl-2-hydroxyethyl(meth)acrylate. These may be used singly or in combination of two or more thereof.

Among the above hydroxy-group-containing (meth)acrylates (a2), hydroxy-group-containing (meth)acrylates having a hydroxyalkyl group having 1 to 10, further 1 to 6, and particularly 2 to 4, carbon atoms, for example, 2-hydroxyethyl(meth)acrylate, 4-hydroxybutyl (meth)acrylate, and 2-hydroxypropyl (meth)acrylate are preferable in terms of reduction of the shear storage elastic modulus (G′) at low temperature. Particularly, primary-hydroxy-group-containing (meth)acrylates, for example, 2-hydroxyethyl(meth)acrylate and 4-hydroxybutyl(meth)acrylate are preferable.

When 2-hydroxyethyl(meth)acrylate and 4-hydroxybutyl (meth)acrylate are used as the hydroxy-group-containing (meth)acrylate (a2), the ratio [2-hydroxyethyl(meth)acrylate/4-hydroxybutyl(meth)acrylate] is preferably 95/5 to 30/70, further 80/20 to 40/60, particularly 75/25 to 45/65, and still particularly 70/30 to 50/50, on a mass basis. An excessively small amount of 2-hydroxyethyl(meth)acrylate tends to decrease an adhesive force when used as the adhesive, and an excessively large amount thereof tends to decrease folding durability when used as the adhesive.

As the hydroxy-group-containing (meth)acrylate (a2), a lower content proportion of a di(meth)acrylate contained as an impurity in the hydroxy-group-containing (meth)acrylate (a2) is more preferable. Specifically, the impurity content in the used hydroxy-group-containing (meth)acrylate is preferably not greater than 0.5 mass %, particularly preferably not greater than 0.2 mass %, and further preferably not greater than 0.1 mass %.

A content of the structural moiety derived from the hydroxy-group-containing (meth)acrylate (a2) relative to the acrylic copolymer is typically 5 to 60%, preferably 8 to 45%, particularly preferably 10 to 35%, further preferably 11 to 30%, and still particularly preferably 12 to 25% in the total mass of the acrylic copolymer.

If the content is excessively low, moisture and heat resistance tends to decrease when used as the adhesive, and if the content is excessively high, the acrylic resin tends to cause a self-crosslinking reaction to decrease heat resistance.

### Copolymerizable Monomer (a3)

The present disclosure preferably further contains the copolymerizable monomer (a3) as the copolymerization component in terms of improvement of a cohesion force, and when used as the adhesiveness, in terms of improvement of an adhesive force.

Examples of the copolymerizable monomer (a3) include methyl(meth)acrylate, ethyl(meth)acrylate, and vinyl acetate. These copolymerizable monomers (a3) may be used singly, or may be used in combination of two or more. Among these, methyl(meth)acrylate and ethyl(meth)acrylate are preferable in terms of improvement of a cohesion force when used as the adhesive.

When the acrylic copolymer has a structural moiety derived from the copolymerizable monomer (a3), a content thereof is preferably typically 1 to 70%, particularly preferably 10 to 60%, and further preferably 15 to 45% in the total mass of the acrylic copolymer. If the content of the copolymerizable monomer (a3) is excessively low, an adhesive force tends to decrease when used as the adhesive. If the content thereof is excessively high, durability tends to decrease when used as the adhesive with a low molecular weight of the acrylic copolymer.

When methyl(meth)acrylate and/or ethyl(meth)acrylate is used as the copolymerizable monomer (a3), a content of a structural moiety derived from methyl(meth)acrylate and/or ethyl(meth)acrylate relative to the acrylic copolymer is typically 1 to 40%, preferably 2 to 30%, further preferably 3 to 25%, and particularly preferably 4 to 10% in the total amount of the acrylic copolymer. An excessively large content of the structural moiety derived from (meth)acrylate and/or ethyl(meth)acrylate tends to deteriorate handling properties in processing due to increase in viscosity. An excessively low content thereof tends to decrease an adhesive force when used as the adhesive.

### Functional-Group-Containing Ethylenically Unsaturated Monomer (a4)

In the present sheet 1, a functional-group-containing ethylenically unsaturated monomer (a4) (except for the hydroxy-group-containing (meth)acrylate (a2)) may be used as necessary as the copolymerizable component of the acrylic copolymer.

Examples of the functional-group-containing ethylenically unsaturated monomer (a4) include functional-group-containing monomers having a nitrogen atom, carboxy-group containing monomers, acetoacetyl-group-containing monomers, isocyanate-group-containing monomers, and glycidyl-group-containing monomers.

Among these, the functional-group-containing ethylenically unsaturated monomer (a4) is preferably the functional-group-containing monomers having a nitrogen atom, particularly preferably amino-group-containing monomers and amide-group-containing monomers, and further preferably amino-group-containing monomers in terms of imparting of cohesion and an action of accelerating crosslinking.

Examples of the amino-group-containing monomers include: primary-amino-group-containing (meth)acrylates such as aminomethyl (meth)acrylate and aminoethyl(meth)acrylate; secondary-amino-group-containing (meth)acrylates such as t-butylaminoethyl(meth)acrylate and t-butylaminopropyl (meth)acrylate; and tertiary-amino-group-containing (meth)acrylates such as diethylaminoethyl(meth)acrylate, dimethylaminoethyl(meth)acrylate, diethylaminoethyl(meth)acrylate, dimethylaminopropyl (meth)acrylate, diethylaminopropyl (meth)acrylate, and dimethylaminopropylacrylamide.

Examples of the amide-group-containing monomers include: (meth)acrylamide; N-alkyl(meth)acrylamides such as N-methyl (meth)acrylamide, N-ethyl(meth)acrylamide, N-propyl(meth)acrylamide, N-n-butyl(meth)acrylamide, diacetone(meth)acrylamide, and N,N′-methylenebis(meth)acrylamide; N, N-dialkyl(meth)acrylamides such as N,N-dimethyl(meth)acrylamide, N, N-diethyl(meth)acrylamide, N, N-dipropyl(meth)acrylamide, N, N-ethylmethylacrylamide, and N, N-diallyl(meth)acrylamide; hydroxyalkyl(meth)acrylamides such as N-hydroxymethyl (meth)acrylamide and N-hydroxyethyl(meth)acrylamide; and alkoxyalkyl(meth)acrylamides such as N-methoxymethyl(meth)acrylamide and N-(n-butoxymethyl)(meth)acrylamide.

Examples of the carboxy-group-containing monomers include (meth)acrylic acid, 2-(meth)acryloyloxyethylhexahydrophthalic acid, 2-(meth)acryloyloxypropylhexahydrophthalic acid, 2-(meth)acryloyloxyethylphthalic acid, 2-(meth)acryloyloxypropylphthalic acid, 2-(meth)acryloyloxyethylmaleic acid, 2-(meth)acryloyloxypropylmaleic acid, 2-(meth)acryloyloxyethylsuccinic acid, 2-(meth)acryloyloxypropylsuccinic acid, crotonic acid, fumaric acid, maleic acid, and itaconic acid.

Examples of the acetoacetyl-group-containing monomers include 2-(acetoacetoxy)ethyl(meth)acrylate and allyl acetoacetate.

Examples of the isocyanate-group-containing monomers include 2-(meth)acryloyloxyethyl isocyanate and an alkylene oxide adduct thereof.

Examples of the glycidyl-group-containing monomers include glycidyl (meth)acrylate and allylglycidyl (meth)acrylate.

These functional-group-containing ethylenically unsaturated monomers (a4) may be used singly, or two or more of these may be used in combination.

When the acrylic copolymer has the structural moiety derived from the functional-group-containing ethylenically unsaturated monomer (a4), a content thereof is typically not greater than 30%, preferably not greater than 20%, further preferably not greater than 10%, and still particularly preferably not greater than 5% in the total mass of the acrylic copolymer. An excessively high content of the structural unit derived from the functional-group-containing ethylenically unsaturated monomer (a4) tends to deteriorate heat resistance of the acrylic copolymer.

### Other Copolymerizable Monomer (a5)

In the present sheet 1, another copolymerizable monomer (a5) may be used as necessary as the copolymerization component of the acrylic copolymer.

Examples of the other copolymerizable monomer (a5) include: (meth)acrylates having an alkoxy alkylene glycol skeleton such as methoxy diethylene glycol (meth)acrylate, methoxy polyethylene glycol (meth)acrylate, butoxy polyethylene glycol (meth)acrylate, methoxy polypropylene glycol (meth)acrylate, butoxy polypropylene glycol (meth)acrylate, methoxy polytetramethylene glycol (meth)acrylate, butoxy polytetramethylene glycol (meth)acrylate, methoxy polyoxyethylene polyoxypropylene glycol (meth)acrylate, and butoxy polyoxyethylene polyoxypropylene glycol (meth)acrylate; aromatic (meth)acrylate monomers such as phenyl (meth)acrylate, benzyl (meth)acrylate, phenoxyethyl(meth)acrylate, phenyl diethylene glycol (meth)acrylate, phenoxy polyethylene glycol (meth)acrylate, phenoxy polyethylene glycol polypropylene glycol (meth)acrylate, and nonylphenol ethylene-oxide adduct (meth)acrylate; and monomers such as acrylonitrile, methacrylonitrile, styrene, α-methylstyrene, vinyl propionate, vinyl stearate, vinyl chloride, vinylidene chloride, alkyl vinyl ether, vinyltoluene, vinylpyridine, vinylpyrrolidone, itaconic acid dialkyl ester, fumaric acid dialkyl ester, allyl alcohol, acryl chloride, methyl vinyl ketone, N-acrylamidemethyltrimethylammonium chloride, allyltrimethylammonium chloride, and dimethylallyl vinyl ketone. These may be used singly, or in combination of two or more thereof.

For a purpose of increasing the molecular weight of the acrylic copolymer, a compound having not less than two ethylenically unsaturated groups etc., such as, for example, ethylene glycol di(meth)acrylate, diethylene glycol di(meth)acrylate, triethylene glycol di(meth)acrylate, polyethylene glycol di(meth)acrylate, propylene glycol di(meth)acrylate, and divinylbenzene, may also be used in combination at a small amount. In this case, these compounds having not less than two ethylenically unsaturated groups have high reactivity, and typically do not remain unreacted when used as the polymerization component of the acrylic copolymer. If a use amount thereof is excessively high, these compounds having not less than two ethylenically unsaturated groups remain unreacted, and the acrylic copolymer tends to gel.

When the acrylic copolymer has the structural moiety derived from the other copolymerizable monomer (a5), a content thereof is typically not greater than 50%, preferably not greater than 40%, and further preferably not greater than 20% in the total mass of the acrylic copolymer. An excessively high content proportion of the other copolymerizable monomer (a5) tends to deteriorate heat resistance and decrease an adhesive force.

The acrylic copolymer used in the present adhesive sheet 1 can be obtained by appropriately selecting and polymerizing the above copolymerization components.

Examples of the method for polymerization of the acrylic copolymer include conventionally known methods such as solution polymerization, suspension polymerization, bulk polymerization, and emulsion polymerization. Among these, the solution polymerization is preferable in terms of ability to produce a safe and stable acrylic copolymer with any monomer composition.

Hereinafter, an example of a preferable method for producing the acrylic copolymer used in the present disclosure will be described.

First, the copolymerization components and a polymerization initiator are mixed or added dropwise in an organic solvent, and solution polymerization is performed to obtain an acrylic resin solution.

### Organic Solvent

Examples of the organic solvent used in the polymerization reaction include: aromatic hydrocarbons such as toluene and xylene; aliphatic hydrocarbons such as hexane; esters such as ethyl acetate and butyl acetate; aliphatic alcohols such as n-propyl alcohol and isopropyl alcohol; and ketones such as acetone, methyl ethyl ketone, methyl isobutyl ketone, and cyclohexanone. These may be used singly or in combination of two or more thereof. Among these solvents, ethyl acetate is preferable.

### Polymerization Initiator

As the polymerization initiator used in the polymerization reaction, azo-type polymerization initiators and peroxide-type polymerization initiators, which are common radical polymerization initiators, may be used. Examples of the azo-type polymerization initiators include 2,2′-azobis(2-methylbutyronitrile), 2,2′-azobisisobutyronitrile, (1-phenylethyl) azodiphenylmethane, 2,2′-azobis(2,4-dimethylvaleronitrile), 2,2′-azobis(2-cyclopropylpropionitrile), and 2,2′-azobis(4-methoxy-2,4-dimethylvaleronitrile). Examples of the peroxide-type polymerization initiators include benzoyl peroxide, di-t-butyl peroxide, cumene hydroperoxide, lauroyl peroxide, t-butyl peroxypivalate, t-hexyl peroxypivalate, t-hexyl peroxyneodecanoate, diisopropyl peroxycarbonate, and diisobutylyl peroxide. These may be used singly or in combination of two or more thereof. Among these, 2,2′-azobis(2,4-dimethylvaleronitrile) is preferable.

A use amount of the polymerization initiator is typically 0.001 to 10 parts by mass, preferably 0.1 to 8 parts by mass, particularly preferably 0.5 to 6 parts by mass, further preferably 1 to 4 parts by mass, still particularly preferably 1.5 to 3 parts by mass, and most preferably 2 to 2.5 parts by mass relative to 100 parts by mass of the copolymerization components. An excessively small use amount of the polymerization initiator tends to decrease a polymerization rate of the acrylic copolymer to increase remained monomers, or tends to increase the weight-average molecular weight of the acrylic copolymer. An excessively large use amount thereof tends to cause gelation of the acrylic copolymer described later.

### Polymerization Condition, Etc.

As for a polymerization condition of the solution polymerization, the polymerization is performed according to a conventionally known polymerization condition. For example, the polymerization components and the polymerization initiator are mixed or added dropwise in the solvent, and the polymerization may be performed under a predetermined polymerization condition.

The polymerization temperature in the polymerization reaction is typically 40 to 120° C., and in the present disclosure, the polymerization temperature is preferably 50 to 90° C., particularly preferably 55 to 75° C., and further preferably 60 to 70° C. in terms of a stable reaction. An excessively high polymerization temperature tends to cause gelation of the acrylic copolymer. An excessively low polymerization temperature decreases activity of the polymerization initiator, and consequently tends to decrease the polymerization rate to increase remained monomers.

The polymerization time of the polymerization reaction (if additional heating described later is performed, a time until the beginning of the additional heating) is not particularly limited. The time from final addition of the polymerization initiator is preferably not shorter than 0.5 hours, particularly preferably not shorter than 1 hour, further preferably not shorter than 2 hours, and still particularly preferably not shorter than 5 hours. An upper limit of the polymerization time is typically 72 hours.

The polymerization reaction is preferably performed with reflux of the solvent in terms of ease of removing heat.

In the production of the acrylic copolymer, the polymerization initiator is preferably pyrolyzed by the additional heating in order to reduce an amount of the remained polymerization initiator.

The additional heating is preferably performed at a temperature higher than a 10-hour half-life temperature of the polymerization initiator, and specifically, the temperature is typically 40 to 150° C., preferably 55 to 130° C., and particularly preferably 75 to 95° C. in terms of gelation inhibition. An excessively high temperature of the additional heating tends to yellow the acrylic copolymer. An excessively low temperature of the additional heating tends to cause remains of the polymerization components and the polymerization initiator to deteriorate stability with time and thermal stability of the acrylic copolymer.

According to the above, the acrylic copolymer can be obtained.

In the acrylic copolymer, a photoactive moiety, for example, a polymerizable carbon-carbon double bond group, may be introduced at the side chain. This photoactive moiety can increase crosslinking efficiency of the adhesive composition to crosslink the adhesive composition at a shorter time, which can improve productivity.

Examples of the method for introducing the polymerizable carbon-carbon double bond group at the side chain of the acrylic copolymer include a method of: producing a copolymer containing the aforementioned hydroxy-group-containing (meth)acrylate (a2) and functional-group-containing ethylenically unsaturated monomer (a4); and then condensing or addition-reacting a compound having a functional group reactive with these functional groups and the polymerizable carbon-carbon double bond group while keeping the activity of the polymerizable carbon-carbon double bond group.

Examples of combinations of these functional groups include an epoxy group (glycidyl group) and a carboxy group, an amino group and a carboxy group, an amino group and an isocyanate group, an epoxy group (glycidyl group) and an amino group, a hydroxy group and an epoxy group, and a hydroxy group and an isocyanate group. Among these combinations of the functional groups, a combination of a hydroxy group and an isocyanate group is preferable in terms of ease of reaction control. Among these, a combination in which the copolymer has the hydroxy group and the compound has the isocyanate group is preferable.

Examples of the isocyanate compound having the polymerizable carbon-carbon double bond group include the aforementioned 2-(meth)acryloyloxyethyl isocyanate and an alkylene oxide adduct thereof.

A content of the compound having the functional group reactive with the functional group and the polymerizable carbon-carbon double bond group is preferably not greater than 10 parts by mass, more preferably not greater than 5 parts by mass, further preferably not greater than 1 part by mass, and particularly preferably not greater than 0.1 part by mass relative to 100 parts by mass of the acrylic copolymer from the viewpoint of improvement of adhesiveness and stress relaxation. The lower limit is typically 0 parts by mass.

A glass transition temperature (Tg) of the acrylic copolymer is preferably not higher than −20° C., more preferably not higher than −23° C., further preferably not higher than −25° C., particularly preferably not higher than −30° C., and still particularly preferably not higher than-40° C. in terms of inhibition of increase in the shear storage elastic modulus (G′) at low temperature. With concern about glue ooze, etc., due to decrease in the shear storage elastic modulus at high temperature, the lower limit of the glass transition temperature (Tg) is typically −70° C., and preferably −50° C.

In the present disclosure, the glass transition temperature (Tg) can be determined by using a dynamic viscoelasticity measurement apparatus and reading a temperature at which a loss tangent (tan δ) when the dynamic viscoelasticity is measured with a shearing mode at a frequency of 1 Hz becomes maximum.

For example, the acrylic copolymer is molded into a cylinder with 8 mm in diameter (height: 1.0 mm), and a loss tangent (tan δ) of this cylinder can be measured by using a viscoelasticity measuring apparatus (“DHR 2,” available from T. A. Instruments) under the following measurement condition.

### (Measurement Condition)

Measurement tool: ϕ 8 mm parallel plate
Strain: 0.1%
Frequency: 1 Hz
Measurement temperature: −60 to 100° C.
Temperature raising rate: 5° C./min

A weight-average molecular weight (Mw) of the acrylic copolymer is preferably not less than 400,000, more preferably not less than 500,000, further preferably not less than 550,000, and particularly preferably not greater than 600,000 from the viewpoint of obtaining the adhesive composition with high cohesiveness.

An upper limit of the weight-average molecular weight (Mw) of the acrylic copolymer is preferably not greater than 1,500,000, more preferably not greater than 1,200,000, further preferably not greater than 1,100,000, and particularly preferably 1,000,000 in terms of operability and stirring uniformity.

In the present disclosure, the weight-average molecular weight (Mw) can be determined as follows, for example.

### (Method for Measuring Weight-Average Molecular Weight)

A measurement sample is prepared by dissolving 4 mg of the acrylic copolymer in 12 mL of tetrahydrofuran (THF), and a molecular weight distribution curve is measured under the following condition using a gel permeation chromatography (GPC) analyzer (“HLC-8320 GPC,” available from Tosoh Co. Ltd.) to determine the weight-average molecular weight (Mw).
Guard column: TSK guard column HXL
Separation column: TSK gel GMHXL (4 columns)
Temperature: 40° C.
Injection amount: 100 μL
In terms of polystyrene
Solvent: THF
Flow rate: 1.0 mL/minute

A content of the acrylic copolymer is typically 10 to 75%, preferably 12 to 73%, more preferably 20 to 71%, and particularly preferably 30 to 69% in the total mass of the adhesive composition.

### Radically Polymerizable Compound (x)

The adhesive composition contains the radically polymerizable compound (x) in addition to the acrylic copolymer. The radically polymerizable compound may be used singly or in combination of two or more thereof.

The radically polymerizable compound (x) has a refractive index of a monomer of preferably less than 1.46, more preferably not greater than 1.45, and particularly preferably not greater than 1.44 from the viewpoint of reducing the refractive index of the adhesive sheet.

An acrylic copolymer typically has a refractive index of about 1.47. When an adhesive sheet is produced by using this acrylic copolymer, it is difficult to reduce the refractive index of the adhesive sheet to not greater than 1.470. In the present disclosure, use of the radically polymerizable compound (x) having a low refractive index can tend to reduce the refractive index of the adhesive sheet.

The radically polymerizable compound (x) preferably has an alkylene glycol skeleton from the viewpoint of reducing the refractive index. There is relationship between the refractive index and the chemical structure, and it is known that a compound having an ether bond has a low refractive index. Thus, use of the radically polymerizable compound having an alkylene glycol skeleton can tend to reduce the refractive index of the adhesive sheet to not greater than 1.470.

When the radically polymerizable compound (x) has the alkylene glycol skeleton, the alkylene glycol skeleton is preferably an alkylene glycol skeleton having an alkylene chain having 2 to 10, further 2 to 8, particularly 2 to 6, and still particularly 2 to 4 carbon atoms, specifically an ethylene glycol skeleton, a propylene glycol skeleton, a butylene glycol skeleton, etc., and more preferably a propylene glycol skeleton from the viewpoints of reducing a refractive index and reducing the shear storage elastic modulus at low temperature while retaining high recovering properties in bending.

The radically polymerizable compound (x) preferably has a urethane bond from the viewpoint of flexibleness.

The content of the radically polymerizable compound (x) is preferably 25 to 1900 parts by mass, more preferably 35 to 740 parts by mass, further preferably 40 to 400 parts by mass, and particularly preferably 45 to 240 parts by mass relative to 100 parts by mass of the acrylic copolymer. Setting the content of the radically polymerizable compound (x) within the above range can tend to provide the adhesive sheet having a low refractive index and excellent flexibleness.

The content of the radically polymerizable compound (x) is preferably 20 to 95%, more preferably 27 to 88%, further preferably 29 to 80%, and particularly preferably 31 to 70% in the total mass of the adhesive composition. Setting the content of the radically polymerizable compound (x) within the above range can tend to provide the adhesive sheet having a low refractive index and excellent flexibleness.

Examples of the radically polymerizable compound (x) include monofunctional radically polymerizable compounds and polyfunctional radically polymerizable compounds. Among these, monofunctional radically polymerizable compounds are preferable.

### Monofunctional Radically Polymerizable Compound

As for the monofunctional radically polymerizable compound, a glass transition temperature of a homo-polymerized polymer is preferably not higher than −40° C., more preferably not higher than −45° C., and further preferably not higher than −50° C. from the viewpoint of reducing the shear storage elastic modulus at low temperature while retaining the high recovering properties in bending.

As for the monofunctional radically polymerizable compound, a glass transition temperature of a homo-polymerized polymer is preferably not lower than −80° C., more preferably not lower than −75° C., and further preferably not lower than −70° C. with concern about glue ooze, etc., due to decrease in the shear storage elastic modulus at high temperature.

Examples of the monofunctional radically polymerizable compound include monofunctional (meth)acrylic monomers and monofunctional (meth)acrylic oligomers. Among these, monofunctional (meth)acrylic oligomers are preferable.

Examples of the monofunctional (meth)acrylic monomers include aliphatic alkyl(meth)acrylates and alicyclic alkyl (meth)acrylates. Specific examples thereof include: monofunctional linear aliphatic (meth)acrylates such as n-butyl(meth)acrylate, pentyl (meth)acrylate, hexyl (meth)acrylate, heptyl (meth)acrylate, n-octyl (meth)acrylate, nonyl (meth)acrylate, decyl (meth)acrylate, undecyl (meth)acrylate, lauryl (meth)acrylate, dodecyl (meth)acrylate, tetradecyl (meth)acrylate, cetyl (meth)acrylate, and stearyl (meth)acrylate; monofunctional branched aliphatic (meth)acrylates such as isobutyl(meth)acrylate, sec-butyl(meth)acrylate, t-butyl (meth)acrylate, isopentyl (meth)acrylate, neopentyl (meth)acrylate, 2-ethylhexyl (meth)acrylate, isooctyl (meth)acrylate, isononyl (meth)acrylate, isodecyl (meth)acrylate, and isostearyl (meth)acrylate; and monofunctional alicyclic (meth)acrylates such as cyclohexyl (meth)acrylate, t-butylcyclohexyl (meth)acrylate, isobornyl (meth)acrylate, 3,3,5-trimethylcyclohexyl (meth)acrylate, dicyclopentanyl (meth)acrylate, dicyclopentenyl (meth)acrylate, and dicyclopentenyloxyethyl(meth)acrylate.

Examples of the monofunctional (meth)acrylic oligomers include oligomers represented by the following general formula (1).

[Formula 1]

CH₂═CR₁—COO—R₂—Z—(R₃O)ₖ—R₄ (1)

In the formula, R₁ represents hydrogen or a methyl group. R₂ represents an alkylene group having 1 to 20 carbon atoms or an alkenyl group having 2 to 20 carbon atoms, and optionally having an ether bond or a cyclic structure in a chain. R₄ represents an alkyl group having 1 to 20 carbon atoms or an alkenyl group having 2 to 20 carbon atoms, and optionally having an ether bond or a cyclic structure in a chain. Z represents one bonding group selected from the group consisting of a urethane bond, an ester bond, an ether bond, a carbonate bond, an amide bond, and a urea bond. R₃ represents an alkylene group being an ethylene group or a propylene group. “k” represents r+s, which is a total number of repeating units (C₂H₄O)ᵣ and (C₃H₆O)ₛ, and an integer of 1 to 500. When both the oxyethylene structure and the oxypropylene structure are present, the structures may be random structure or block structure.

The positive number “k” in the general formula (1) is preferably 10 to 500, more preferably 100 to 450, and further preferably 200 to 400 from the viewpoints of reducing the refractive index and reducing the shear storage elastic modulus at low temperature while retaining the high recovering properties in bending.

Among these, the monofunctional (meth)acrylic oligomer is preferably a monofunctional urethane (meth)acrylate, a monofunctional polyester (meth)acrylate, a monofunctional epoxy (meth)acrylate, etc., and more preferably a monofunctional urethane (meth)acrylate.

Since the monofunctional urethane (meth)acrylate has high polarity and long chain length, the polymer chains entwine to yield high recovering properties. In addition, the oxypropylene structure with high molecular rotatability yields a low shear storage elastic modulus, which is particularly effective.

The weight-average molecular weight (Mw) of the monofunctional (meth)acrylic oligomer is preferably not greater than 30,000, more preferably not greater than 28,000, and further preferably not greater than 25,000 from the viewpoint of reducing the shear storage elastic modulus at low temperature while retaining the high recovering properties in bending.

A lower limit of the weight-average molecular weight (Mw) of the monofunctional (meth)acrylic oligomer is preferably not less than 3,000, more preferably not less than 4,000, and further preferably not less than 5,000 from the viewpoint of preventing deterioration of adhesiveness due to bleed out while retaining the high recovering properties in bending.

The weight-average molecular weight (Mw) of the monofunctional (meth)acrylic oligomer can be determined according to the aforementioned “Method for Measuring Weight-Average Molecular Weight” of the acrylic copolymer.

### Polyfunctional Radically Polymerizable Compound

Examples of the polyfunctional radically polymerizable compound include polyfunctional (meth)acrylic monomers and polyfunctional (meth)acrylic oligomers.

Examples of the polyfunctional (meth)acrylic monomer include: bifunctional (meth)acrylates such as 1,4-butanediol di(meth)acrylate, glycerol di(meth)acrylate, neopentyl glycol di(meth)acrylate, glycerol glycidyl ether di(meth)acrylate, tricyclodecanedimethanol dimethacrylate, tricyclodecanedimethanol di(meth)acrylate, bisphenol A polyethoxy di(meth)acrylate, bisphenol A polypropoxy di(meth)acrylate, bisphenol F polyethoxy di(meth)acrylate, ethylene glycol di(meth)acrylate, neopentyl glycol di(meth)acrylate, polyethylene glycol di(meth)acrylate, polypropylene glycol di(meth)acrylate, polytetramethylene glycol di(meth)acrylate, neopentyl glycol hydroxypivalate di(meth)acrylate, and di(meth)acrylate of ε-caprolactone adduct of neopentyl glycol hydroxypivalate; and tri- or more functional (meth)acrylates such as trimethylolpropanetrioxyethyl (meth)acrylate, ε-caprolactone-modified tris(2-hydroxyethyl) isocyanurate tri(meth)acrylate, pentaerythritol tri(meth)acrylate, propoxylated pentaerythritol tri(meth)acrylate, ethoxylated pentaerythritol tri(meth)acrylate, pentaerythritol tetra(meth)acrylate, propoxylated pentaerythritol tetra(meth)acrylate, ethoxylated pentaerythritol tetra(meth)acrylate, dipentaerythritol hexa(meth)acrylate, tris(acryloxyethyl) isocyanurate, dipentaerythritol hexa(meth)acrylate, dipentaerythritol penta(meth)acrylate, tripentaerythritol hexa(meth)acrylate, tripentaerythritol penta(meth)acrylate, trimethylolpropane tri(meth)acrylate, trimethylolpropane polyethoxy tri(meth)acrylate, and ditrimethylolpropane tetra(meth)acrylate.

Examples of the polyfunctional (meth)acrylic oligomers include polyfunctional (meth)acrylic oligomers such as polyfunctional polyester (meth)acrylic oligomers, polyfunctional epoxy (meth)acrylic oligomers, polyfunctional urethane (meth)acrylic oligomers, and polyfunctional polyether (meth)acrylic oligomers.

When the polyfunctional (meth)acrylic monomer or the polyfunctional (meth)acrylic oligomer is used, these serve also as a crosslinker.

### Photopolymerization Initiator

The adhesive composition preferably further contains a photopolymerization initiator in addition to the acrylic copolymer and the radically polymerizable compound (x). The photopolymerization initiator may be any compound to generate radicals by active energy ray.

The photopolymerization initiator is largely classified into two types with its radical generation mechanism: a cleavage-type photopolymerization initiator in which a single bond in the initiator itself can be cleaved and decomposed to generate radicals; and a hydrogen abstraction-type photopolymerization initiator in which an excited initiator and a hydrogen donor in the system can form an exciplex to transfer hydrogen in the hydrogen donor.

The photopolymerization initiator may be any of the cleavage-type photopolymerization initiator and the hydrogen abstraction-type photopolymerization initiator, each of them may be used singly or may be mixed for use, and one or two or more of them may be each used in combination.

In the present disclosure, the hydrogen abstraction-type photopolymerization initiator is preferably used in terms of efficient crosslinking without requiring a functional group such as a polymerizable carbon-carbon double bond group in the acrylic copolymer itself.

Examples of the cleavage-type photopolymerization initiator include 2,2-dimethoxy-1,2-diphenylethan-1-one, 1-hydroxycyclohexyl phenyl ketone, 2-hydroxy-2-methyl-1-phenylpropan-1-one, 1-(4-(2-hydroxyethoxy)phenyl)-2-hydroxy-2-methyl-1-propan-1-one, 2-hydroxy-1-[4-{4-(2-hydroxy-2-methyl-propionyl)benzyl} phenyl]-2-methylpropan-1-one, oligo (2-hydroxy-2-methyl-1-(4-(1-methylvinyl)phenyl) propanone), methyl phenylglyoxylate, 2-benzyl-2-dimethylamino-1-(4-morpholinophenyl) butan-1-one, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, bis(2,4,6-trimethylbenzoyl)-phenylphosphine oxide, 2,4,6-trimethylbenzoyldiphenylphosphine oxide, (2,4,6-trimethylbenzoyl)ethoxyphenylphosphine oxide, bis(2,6-dimethoxybenzoyl)-2,4,4-trimethylpentylphosphine oxide, and derivatives thereof.

Examples of the hydrogen abstraction-type photopolymerization initiator include benzophenone, 4-methylbenzophenone, 2,4,6-trimethylbenzophenone, 4-phenylbenzophenone, 3,3′-dimethyl-4-methoxybenzophenone, 4-(meth)acryloyloxybenzophenone, methyl 2-benzoylbenzoate, methyl benzoylformate, bis(2-phenyl-2-oxoacetate)oxybisethylene, 4-(1,3-acryloyl-1,4,7,10,13-pentaoxotridecyl)benzophenone, thioxanthone, 2-chlorothioxanthone, 3-methylthioxanthone, 2,4-dimethylthioxanthone, 2-methylanthraquinone, 2-ethylanthraquinone, 2-t-butylanthraquinone, 2-aminoanthraquinone, and derivatives thereof. Among these, 4-methylbenzophenone and 2,4,6-trimethylbenzophenone are preferable.

When the photopolymerization initiator is used, a content thereof is preferably typically 0.1 to 10 parts by mass, specifically preferably 0.5 to 6 parts by mass, and still specifically preferably 1 to 4 parts by mass relative to 100 parts by mass of the acrylic copolymer. The content of not less than the above lower limit tends to prevent curing failure, and the content of not greater than the above upper limit tends to easily inhibit decrease in solution stability, such as precipitation from the adhesive composition, to inhibit problems of embrittlement and coloring.

### Thermal Crosslinker

The adhesive composition may contain a thermal crosslinker in terms of more increase in crosslinking density to improve long-term reliability.

Examples of such a thermal crosslinker include isocyanate crosslinker, epoxy crosslinker, aziridine crosslinker, melamine crosslinker, aldehyde crosslinker, amine crosslinker, and metal-chelate crosslinker. Among these, the isocyanate crosslinker is preferably used in terms of excellent reactivity with the acrylic copolymer.

When the thermal crosslinker is used, a content thereof is typically 0.01 to 10 parts by mass, preferably 0.02 to 7 parts by mass, and more preferably 0.1 to 5 parts by mass relative to 100 parts by mass of the acrylic copolymer.

### Other Components

The adhesive composition may appropriately contain various additives as “other components” as necessary to an extent not impairing the effect of the present disclosure. Examples of the other components include silane-coupling agent, UV absorber, antirust agent, tackifier resin, oxidation inhibitor, light stabilizer, metal deactivator, antiaging agent, moisture absorber, inorganic particles, and refractive-index regulator.

As necessary, reaction catalysts such as tertiary amine compound, quaternary ammonium compound, and tin laurate compound may be appropriately contained.

These may be used singly, or two or more of these may be used in combination.

### (Silane-Coupling Agent)

The silane-coupling agent is an organic silicon compound having one or more reactive functional groups and one or more alkoxy groups bonded to a silicon atom in the structure. Examples of the reactive functional group include epoxy group, (meth)acryloyl group, mercapto group, hydroxy group, carboxy group, amino group, amide group, and isocyanate group. Among these, epoxy group and mercapto group are preferable in terms of balance of durability.

As the alkoxy group bonded to a silicon atom, an alkoxy group having 1 to 8 carbon atoms is preferably contained in terms of durability and storage stability, and a methoxy group and an ethoxy group are particularly preferable. The silane-coupling agent may have an organic substituent other than the reactive functional group and the alkoxy group bonded to a silicon atom, such as, for example, alkyl group and phenyl group.

Examples of the silane-coupling agent include: monomer-type epoxy-group-containing silane-coupling agents being silane compounds such as 3-glycidoxypropyltrimethoxysilane, 3-glycidoxypropyltriethoxysilane, 3-glycidoxypropylmethyldiethoxysilane, 3-glycidoxypropylmethyldimethoxysilane, and 2-(3,4-epoxycyclohexyl)ethyltrimethoxysilane; oligomer-type epoxy-group-containing silane-coupling agents being silane compounds in which a part of the above silane compound is hydrolytically condensing-polymerized or in which the above silane compound and an alkyl group-containing silane compound, such as methyltriethoxysilane, ethyltriethoxysilane, methyltrimethoxysilane, and ethyltrimethoxysilane, are co-condensed; monomer-type mercapto-group-containing silane-coupling agents being silane compounds such as 3-mercaptopropyltrimethoxysilane, 3-mercaptopropyltriethoxysilane, γ-mercaptopropyldimethoxymethylsilane, and 3-mercaptopropylmethyldimethoxysilane; oligomer-type mercapto-group-containing silane-coupling agents being silane compounds in which a part of the above silane compound is hydrolytically condensing-polymerized or in which the above silane compound and an alkyl-group-containing silane compound, such as methyltriethoxysilane, ethyltriethoxysilane, methyltrimethoxysilane, and ethyltrimethoxysilane, are co-condensed; (meth)acryloyl-group-containing silane-coupling agents such as 3-acryloxypropyltrimethoxysilane, 3-methacryloxypropyltrimethoxysilane, 3-methacryloxypropylmethyldiethoxysilane, 3-methacryloxypropyltriethoxysilane, and 3-acryloxypropyltrimethoxysilane; amino-group-containing silane-coupling agents such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene) propylamine, and N-phenyl-3-aminopropyltrimethoxysilane; isocyanate-group-containing silane-coupling agents such as 3-isocyanatepropyltriethoxysilane; and vinyl-group-containing silane-coupling agents such as vinyltrimethoxysilane and vinyltriethoxysilane. These may be used singly or in combination of two or more thereof.

Among these, the epoxy-group-containing silane-coupling agent and the mercapto-group-containing silane coupling agent are preferably used, and specifically, the epoxy-group-containing silane-coupling agent is preferable in terms of excellent durability.

A content of the silane-coupling agent is preferably 0.005 to 10 parts by mass, particularly preferably 0.01 to 5 parts by mass, and further preferably 0.05 to 1 part by mass relative to 100 parts by mass of the acrylic copolymer. The content of not less than the above lower limit tends to improve durability, and the content of not greater than the above upper limit tends to improve durability, and the content of not greater than the above upper limit tends to improve the durability.

### (UV Absorber)

Examples of the UV absorber include benzophenone UV absorbers, benzotriazole UV absorbers, triazine UV absorbers, salicylic acid UV absorbers, cyanoacrylate UV absorbers, and benzoxazine UV absorbers. These UV absorbers may be used singly or in a combination of two or more thereof.

A content of the UV absorber is preferably 0.01 to 20 parts by mass, particularly preferably 0.1 to 15 parts by mass, and further preferably 0.5 to 10 parts by mass relative to 100 parts by mass of the acrylic copolymer. The content of not less than the above lower limit tends to improve light-resistant reliability, and the content of not greater than the above upper limit tends to improve yellowing resistance.

### (Antirust Agent)

The antirust agent is preferably triazoles and benzotriazoles, for example. The antirust agent can prevent corrosion of an optical member. These may be used singly or in combination of two or more thereof.

A content of the antirust agent is preferably 0.01 to 5 parts by mass, and specifically preferably not less than 0.1 part by mass and not greater than 3 parts by mass relative to 100 parts by mass of the acrylic copolymer.

A content of the other components is preferably not greater than 5 parts by mass, particularly preferably not greater than 1 part by mass, and further preferably not greater than 0.5 parts by mass relative to 100 parts by mass of the acrylic copolymer. An excessively large content thereof tends to decrease compatibility with the acrylic copolymer to deteriorate durability.

The adhesive composition is prepared by mixing predetermined amounts of the acrylic copolymer, the radically polymerizable compound (x), preferably further the photopolymerization initiator, and as necessary the thermal crosslinker and the other components.

### <Method for Producing the Present Adhesive Sheet 1>

Next, a method for producing the present adhesive sheet 1 will be described.

Note that the following description is an example of the method for producing the present adhesive sheet 1, and the present adhesive sheet 1 is not limited to those produced by this producing method.

In the production of the present adhesive sheet 1, the adhesive composition for forming the present adhesive sheet 1, which contains the acrylic copolymer, the radically polymerizable compound (x), further the photopolymerization initiator, and as necessary the thermal crosslinker and other components, is prepared, this adhesive composition is formed into a sheet shape and subjected to crosslinking, namely a polymerization reaction, to be cured, and as necessary subjected to appropriate processing to produce the present adhesive sheet 1.

In the production of the present adhesive sheet 1, the adhesive composition for forming the present adhesive sheet 1 is prepared as above, this composition is applied on a member sheet or a flexible image display device constituent member, and the adhesive composition is cued to form the present adhesive sheet 1. Note that the method for producing the present adhesive sheet 1 is not limited to this method.

When the adhesive composition for forming the present adhesive sheet 1 is prepared, the raw materials are kneaded by using a temperature-controllable kneading apparatus (for example, a uniaxial extruder, a biaxial extruder, a planetary mixer, a biaxial mixer, and a pressurizing kneader).

When the raw materials are kneaded, the additives such as the silane-coupling agent and the oxidation inhibitor may be blended with the resin in advance and then supplied into the kneading apparatus, all the materials may be melt-mixed in advance and then supplied, or only the additives may be condensed into the resin in advance to produce a master batch and then supplied.

As the method for forming the adhesive composition into a sheet, usable is a known method such as, for example, a wet-laminating method, a dry-laminating method, an extrusion casting method using a T-die, an extrusion laminating method, a calendar method, an inflation method, an injection molding method, and a liquid-injecting curing method. Among these, a wet-laminating method, an extrusion casting method, and an extrusion laminating method are preferable for producing the sheet.

The adhesive composition can be cured by irradiation with active energy ray. The formed product of the adhesive composition, for example a sheet-shaped formed product, is irradiated with active energy ray to produce the present adhesive sheet 1. In addition to the irradiation with active energy ray, heating may be performed to further cure the composition.

Irradiation energy, an irradiation time, an irradiation method, etc., of the active energy radiation are not particularly limited as long as the photopolymerization initiator is activated to polymerize the monomer components.

When the hydrogen abstraction-type photopolymerization initiator is used as the photopolymerization initiator, the acrylic copolymer is also subjected to the hydrogen abstraction reaction and the acrylic copolymer is incorporated into the crosslinked structure, which can form a crosslinked structure with many crosslinking points.

Therefore, the present adhesive sheet 1 is preferably a cured product produced by using the hydrogen abstraction-type photopolymerization initiator.

Examples of the active energy radiation in the irradiation with active energy radiation include: rays such as far UV, UV, near UV, infrared ray, and visible ray; and ionizing radiations such as X-ray, α-ray, β-ray, γ-ray, electron beam, proton beam, and neutron beam. Among these, UV is preferable from the viewpoints of reduction in damage of constituent members of an optical apparatus and reaction control. In addition, curing with UV irradiation is advantageous in terms of a curing rate, easy availability of the irradiation apparatus, price, etc.

Examples of a light source of the UV irradiation include use of a high-pressure mercury lamp, an ultrahigh-pressure mercury lamp, a low-pressure mercury lamp, a carbon arc lamp, a metal halide lamp, a xenon lamp, a chemical lamp, an electrodeless discharge lamp, or an LED, which emit light with a wavelength region of 150 to 450 nm. Among these, a high-pressure mercury lamp is preferably used.

The irradiation is performed under a condition of an irradiation dose (integrated light quantity) of the active energy of preferably 0.03 to 3 J/cm², more preferably 0.1 to 2 J/cm², and further preferably 0.3 to 1.5 J/cm² in terms of curing.

Another embodiment of the method for producing the present adhesive sheet 1 may be performed by dissolving the adhesive composition in an appropriate solvent and by using each of coating techniques.

When the coating technique is used, the present adhesive sheet 1 can be obtained by thermal curing, other than curing with the aforementioned irradiation with active energy ray. With coating, the thickness of the present adhesive sheet 1 can be regulated with an applying thickness and a solid-content concentration of the coating liquid.

For example, the adhesive composition is dissolved in a solvent, then applied on a release film and dried, and cured by irradiation with the active energy to form the present adhesive sheet. A release film may be further laminated as necessary. In this case, it is acceptable that the release film is coated and dried, the adhesive composition is cured by irradiation with the active energy, and the release film may be laminated thereto. Alternatively, it is acceptable that the release film is coated and dried, the release film is laminated, and then the adhesive composition is cured by irradiation with the active energy to form the present adhesive sheet 1.

Such a solvent is not particularly limited as long as the solvent dissolves the adhesive composition. Examples of the solvent include: ester solvents such as methyl acetate, ethyl acetate, butyl acetate, methyl acetoacetate, and ethyl acetoacetate; ketone solvents such as acetone, methyl ethyl ketone, and methyl isobutyl ketone; aromatic solvents such as toluene and xylene; and alcohol solvents such as methanol, ethanol, and propyl alcohol. These may be used singly or in combination of two or more thereof. Among these, ethyl acetate, acetone, methyl ethyl ketone, and toluene are preferable in terms of solubility, drying property, price, etc., and ethyl acetate is particularly preferably used.

A content of the solvent is preferably not greater than 600 parts by mass, more preferably not greater than 500 parts by mass, further preferably not greater than 400 parts by mass, and particularly preferably not greater than 300 parts by mass relative to 100 parts by mass of the acrylic copolymer in terms of drying property. Meanwhile, the content is preferably not less than 1 part by mass, more preferably not less than 50 parts by mass, further preferably not less than 100 parts by mass, and particularly preferably not less than 150 parts by mass.

The coating can be performed by a commonly used method such as roll coating, die coating, gravure coating, comma coating, screen printing, and bar coating, for example.

A content of the solvent in the adhesive composition after the drying is preferably not greater than 1 mass %, more preferably not greater than 0.5 mass %, particularly preferably not greater than 0.1 mass %, and most preferably 0 mass %.

The drying temperature is typically 40 to 150° C., more preferably 45 to 140° C., further preferably 50 to 130° C., and particularly preferably 55 to 120° C. The drying temperature within the above range can efficiently and relatively safely remove the solvent while inhibiting thermal deformation of the release film.

The drying time is typically 1 to 30 minutes, more preferably 3 to 25 minutes, and further preferably 5 to 20 minutes. The drying time within the above range can efficiently and sufficiently remove the solvent.

Examples of the drying method include drying with a drying apparatus or a heat roller, and drying by blowing hot air to the film. Among these, a drying apparatus is preferably used in terms of uniform and easy drying. These may be used singly or in combination of two or more thereof.

A release film may be provided on at least one surface of the present adhesive sheet 1 obtained above from the viewpoints of prevention of blocking and prevention of foreign matter adhesion.

The present adhesive sheet 1 can be provided also as an adhesive sheet with a release film (adhesive sheet laminate) having a configuration in which a release film is laminated onto one surface or both surfaces of an adhesive layer (the present adhesive sheet) composed of the adhesive composition.

When the release film is provided on both the surfaces of the present adhesive sheet 1, preferable is a laminate configuration of laminating a light-release film exhibiting a relatively low releasing force and a heavy-release film exhibiting a relatively high releasing force.

In use of the adhesive sheet with a release film having the release film provided on both the surfaces, one release film (light-release film) is released to expose one surface of the adhesive sheet and adhere to a member sheet or a flexible image display device constituent member (referred to as “first member”), and the other release film (heavy-release film) is released to expose the other surface of the adhesive sheet and adhere to a member sheet or a flexible image display device constituent member (referred to as “second member”).

As such a release film, known release films may be appropriately used.

As a material of the release film, a film such as a polyester film, a polyolefin film, a polycarbonate film, a polystyrene film, an acryl film, a triacetylcellulose film, and a fluororesin film that are subjected to a releasing treatment by applying a releasing agent such as a silicone resin; and release paper, etc., may be appropriately selected for use, for example.

Among these, a polyester film, further specifically a polyethylene terephthalate (PET) film, particularly a biaxial-stretched PET film is preferable in terms of excellent transparency, mechanical strength, heat resistance, flexibility, etc. Usable is a release film in which a release layer formed by curing a curable silicone releasing agent mainly containing a silicone resin is provided on the substrate.

When an adhesive sheet having excellent flexibleness is used as the adhesive sheet with a release film, a high releasing force of the release film typically tends to deform the adhesive sheet when releasing the release film to cause a released trace because the adhesive sheet is soft.

Thus, the release film used for the adhesive sheet having excellent flexibleness, specifically the light-release film, is preferably a release film that can be released with a further smaller force than a light-release film conventionally and commonly used.

However, increasing the thickness of the releasing agent layer in order to reduce the releasing force of the release film may cause the component derived from the releasing agent layer to be transferred onto the surface of the adhesive sheet to impair reliability of the adhesive sheet with some types of the used releasing agent. Thus, the release film preferably has good releasing properties from the adhesive sheet and low transferring properties of the releasing agent to the adhesive sheet.

The releasing force between the present adhesive sheet 1 and the release film is preferably 0.05 to 1.5 N/cm, more preferably 0.06 to 1.2 N/cm, and further preferably 0.07 to 1.0 N/cm. The releasing force between the present adhesive sheet 1 and the release film is a measured value with a 180°-releasing test at a test speed: 300 m/min. The releasing force between the present adhesive sheet 1 and the release film within the above range can prevent a released trace when releasing the present adhesive sheet 1 from the release film.

A peak intensity of silicon atom, which is measured by using a fluorescence X-ray analyzer on the exposed adhesive surface by releasing the release film from the present adhesive sheet 1, is preferably not greater than 100 cps. The peak intensity of not greater than 100 cps prevents impairing of reliability when the adhesive sheet is used as a laminate for an image display device constituent due to the releasing agent transferred to the adhesive sheet surface, which is preferable. From the above viewpoint, the peak intensity is more preferably not greater than 90 cps, further preferably not greater than 80 cps, and still particularly preferably not greater than 70 cps. The lower limit is typically 0 cps.

A thickness of the release film is not particularly limited. From the viewpoints of processability and handleability, for example, the thickness is preferably 10 to 250 μm, specifically preferably 25 to 200 μm, and further specifically preferably 35 to 190 μm.

As necessary, emboss processing or texturing processing (such as a cone, pyramid shape, or hemispherical shape) may be performed. For a purpose of improving adhesiveness to each member sheet, the surface may be subjected to surface treatments such as a corona treatment, a plasma treatment, and a primer treatment.

The present adhesive sheet 1 may be a single-layer sheet composed of only the acrylic adhesive layer formed from the adhesive composition or may be a multilayer sheet in which a plurality of acrylic adhesive layers or other adhesive agent layers are laminated.

### <The Present Adhesive Sheet 2>

As noted above, the present adhesive sheet 2 has an acrylic adhesive layer, and the acrylic adhesive layer is a cured reaction product formed with a syrup composition containing an alkyl (meth)acrylate (a1), a hydroxy-group-containing (meth)acrylate (a2), and a radically polymerizable compound (x).

Hereinafter, each component contained in the acrylic adhesive layer (syrup composition) will be described in detail.

### Alkyl (Meth)acrylate (a1)

Examples of the alkyl(meth)acrylate (a1) include same as the alkyl(meth)acrylate (a1) described in the present adhesive sheet 1, and types of preferable monomers, etc., are also same as of the alkyl (meth)acrylate (a1) described in the present adhesive sheet 1.

A content of a structural moiety derived from the alkyl (meth)acrylate (a1) is preferably 2 to 80% in a total mass of the acrylic adhesive layer (syrup composition) in terms of inhibiting increase in the shear storage elastic modulus (G′) at low temperature, and more preferably 5 to 55% and particularly preferably 10 to 50%. The content of the structural moiety derived from the alkyl(meth)acrylate (a1) of not lower than the above lower limit is preferable in terms of ability to inhibit increase in the shear storage elastic modulus (G′) at low temperature. The content of not greater than the above upper limit is preferable in terms of ability to achieve both adhesiveness etc. and other physical properties.

### Hydroxy-Group-Containing (Meth)acrylate (a2)

Examples of the hydroxy-group-containing (meth)acrylate (a2) include same as the hydroxy-group-containing (meth)acrylate (a2) described in the present adhesive sheet 1, and types of preferable monomers, etc., are also same as of the hydroxy-group-containing (meth)acrylate (a2) described in the present adhesive sheet 1.

A content of a structural moiety derived from the hydroxy-group-containing (meth)acrylate (a2) is typically 0.5 to 60%, preferably 0.5 to 30%, particularly preferably 1 to 25%, further preferably 1.5 to 20%, and still particularly preferably 2 to 20% in the total mass of the acrylic adhesive layer (syrup composition).

Setting the content to be not lower than the above lower limit tends to inhibit deterioration of humidity and heat resistance when used as the adhesive. Setting the content to be not greater than the above upper limit facilitates a self-crosslinking reaction of the adhesive layer to tend to inhibit deterioration of heat resistance.

### Radically Polymerizable Compound (x)

Examples of the radically polymerizable compound (x) include same as the radically polymerizable compound (x) described in the present adhesive sheet 1 that are not overlapped with (a3) to (5). Preferable compounds, physical properties, etc. of the radically polymerizable compound (x) are same as those of the radically polymerizable compound (x) described in the present adhesive sheet 1.

A content of a structural moiety derived from the radically polymerizable compound (x) is preferably 20 to 95%, more preferably 27 to 88%, further preferably 29 to 80%, and particularly preferably 31 to 70% in the total mass of the acrylic adhesive layer (syrup composition). Setting the content of the radically polymerizable compound (x) to be within the above range tends to yield the adhesive sheet having a low refractive index and excellent flexibleness.

The syrup composition may contain the copolymerizable monomer (a3), the functional-group-containing monomer (a4), and the other copolymerizable monomer (a5), which are described in the present adhesive sheet 1. The types of preferable monomers thereof etc. are the same as those described in the present adhesive sheet 1.

When the acrylic adhesive layer has a structural moiety derived from the copolymerizable monomer (a3), a content thereof is typically 1 to 70%, preferably 10 to 60%, and particularly preferably 15 to 45% in the total mass of the acrylic adhesive layer (syrup composition).

When the acrylic adhesive layer has a structural moiety derived from the functional-group-containing monomer (a4), a content thereof is typically not greater than 30%, preferably not greater than 20%, particularly preferably not greater than 10%, and still particularly preferably not greater than 5% in the total mass of the acrylic adhesive layer (syrup composition).

When the acrylic adhesive layer has a structural moiety derived from the other copolymerizable monomer (a5), a content thereof is typically not greater than 50%, preferably not greater than 40%, and particularly preferably not greater than 20% in the total mass of the acrylic adhesive layer (syrup composition).

The acrylic adhesive layer preferably further contains the photopolymerization initiator described in the aforementioned present adhesive sheet 1, and may contain the thermal crosslinker and the other components that are described in the aforementioned present adhesive sheet 1.

### Photopolymerization Initiator

The photopolymerization initiator is not particularly limited as long as it is same as the photopolymerization initiator described in the aforementioned present adhesive sheet 1. From the viewpoint of efficiently progressing the polymerization reaction, the photopolymerization initiator preferably contains a cleavage-type photopolymerization initiator, and among the aforementioned cleavage-type photopolymerization initiators, 2,2-dimethoxy-1,2-diphenylethan-1-one, 2-hydroxy-2-methyl-1-phenyl-propan-1-one, bis(2,4,6-trimethylbenzoyl)-phenylphosphine oxide, 2,4,6-trimethylbenzoyldiphenylphosphine oxide, and (2,4,6-trimethylbenzoyl)ethoxyphenylphosphine oxide are particularly preferable.

From the viewpoint of efficiently forming the crosslinked structure, the photopolymerization initiator preferably contains a hydrogen abstraction-type photopolymerization initiator, and benzophenone, 4-methylbenzophenone, 2,4,6-trimethylbenzophenone, 4-phenylbenzophenone, 3,3′-dimethyl-4-methoxybenzophenone, and 4-(meth)acryloyloxybenzophenone are particularly preferable.

The photopolymerization initiator may contain two or more types selected from the group consisting of the cleavage-type photopolymerization initiator and/or the hydrogen abstraction-type photopolymerization initiator.

When the photopolymerization initiator is used, a content thereof is preferably 0.1 to 10 parts by mass, specifically preferably 0.5 to 6 parts by mass, and further specifically preferably 1 to 4 parts by mass relative to 100 parts by mass of the copolymerization components contained in the syrup composition such as the alkyl (meth)acrylate (a1), the hydroxy-group-containing (meth)acrylate (a2), the radically polymerizable compound (x), the copolymerizable monomer (a3), the functional-group-containing monomer (a4), and the other copolymerizable monomer (a5). The content of not lower than the above lower limit tends to prevent curing failure. The content of not greater than the above upper limit tends to easily inhibit decrease in stability, such as precipitation from the adhesive sheet, to easily inhibit problems of embrittlement and coloring.

### Thermal Crosslinker

As the thermal crosslinker, an isocyanate thermal crosslinker is preferably used in terms of excellent reactivity with the acrylic copolymer.

When the thermal crosslinker is used, a content thereof is typically 1 to 30%, and preferably 5 to 20% in the total mass of the acrylic adhesive layer (syrup composition).

### Other Components

The other components are preferably silane-coupling agent, UV absorber, and antirust agent. The types etc. of preferable silane-coupling agent, UV absorber, and antirust agent are same as described in the present adhesive sheet 1.

When the silane-coupling agent is used, a content thereof is typically 0.005 to 5%, preferably 0.01 to 3%, and further preferably 0.05 to 1% in the total mass of the acrylic adhesive layer (syrup composition). The content within the above range tends to improve durability.

When the acrylic adhesive layer contains the UV absorber, a content thereof is typically 0.001 to 20%, preferably 0.1 to 15%, and further preferably 0.5 to 10% in the total mass of the acrylic adhesive layer (syrup composition). The content of not lower than the above lower limit tends to improve light-resistant reliability, and the content of not greater than the above upper limit tends to improve yellowing resistance.

When the acrylic adhesive layer contains the antirust agent, a content thereof is typically not greater than 5%, preferably not greater than 1%, and further preferably not greater than 0.5% in the total mass of the acrylic adhesive layer (syrup composition). If the content is excessively high, the compatibility decreases to tend to deteriorate durability.

### <Method for Producing the Present Adhesive Sheet 2>

Next, a method for producing the present adhesive sheet 2 will be described.

Note that the following description is an example of the method for producing the present adhesive sheet 2, and the present adhesive sheet 2 is not limited to those produced by the producing method.

For producing the present adhesive sheet 2, the copolymerization components such as the alkyl(meth)acrylate (a1), the hydroxy-group-containing (meth)acrylate (a2), the radically polymerizable compound (x), the copolymerizable monomer (a3), the functional-group-containing monomer (a4), and the other copolymerizable monomer (a5); the photopolymerization initiator; etc. are typically kneaded to prepare the syrup composition. Then, this syrup composition is irradiated with active energy ray to perform pre-polymerization. Thereafter, an additional photopolymerization initiator, the thermal crosslinker, and the other components are added into the syrup composition, the composition is applied on a release film etc. by each of coating methods, and the coating is further irradiated with active energy ray or heated for curing to obtain the present adhesive sheet 2.

The radically polymerizable compound (x), the thermal crosslinker, and the other components may be added into the syrup composition in advance, or may be added into the syrup composition after the pre-polymerization. Further, the pre-polymerization and the curing may be performed in a single step.

As another embodiment of the method for producing the present adhesive sheet 2, the syrup composition is dissolved in a solvent, and then applied on a release film, dried, and irradiated with active energy ray for performing pre-polymerization and curing to form the present adhesive sheet 2.

In the method for producing the present adhesive sheet 2, the release film, the active energy ray, the solvent, etc., and a kneading method, a coating method, a drying condition, etc. are according to the description of the present adhesive sheet 1.

The present adhesive sheet 2 obtained as above may be a single-layer sheet having only the acrylic adhesive layer or may be a multilayer sheet in which a plurality of the acrylic adhesive layers or other adhesive agent layers are laminated. The present adhesive sheet 2 can be provided also as an adhesive sheet with a release film (adhesive sheet laminate) having a configuration in which a release film is laminated onto one surface or both surfaces of an adhesive layer (the present adhesive sheet) composed of the adhesive composition.

### <Physical Properties of the Present Sheet>

The present adhesive sheets 1 and 2 (hereinafter, simply referred to as “the present adhesive sheet”) can have the following physical properties.

A refractive index of the present adhesive sheet is not greater than 1.470, preferably not greater than 1.469, more preferably not greater than 1.467, further preferably not greater than 1.465, and furthermore preferably not greater than 1.464. A lower limit of the refractive index of the present adhesive sheet is preferably not less than 1.450, and more preferably not less than 1.460.

Examples of a method for regulating the refractive index of the present adhesive sheet include: a method of using a monomer having a relatively low refractive index among the aforementioned alkyl (meth)acrylate (a1), for example, an alkyl(meth)acrylate with an alkyl group having not less than 4, particularly not less than 6, still particularly not less than 8 carbon atoms, as the constitutional moiety of the acrylic copolymer, and regulating a content thereof; a method of using a (meth)acrylate monomer having an alkylene glycol structure as the constitutional moiety; and a method of regulating the structure and the blending amount of the radically polymerizable compound (x). Within a range not impairing compatibility and transparency of the adhesive composition, a refractive-index regulator may be added.

The refractive index refers to a refractive index on a surface (acrylic adhesive layer) of the present adhesive sheet. The refractive index can be measured by using a commercial refractive index measurement device (Abbe's refractometer) under a condition of a measurement wavelength of 589 nm and a measurement temperature of 25° C. Specifically, the refractive index can be measured by a method described in Examples described later.

### (Shear Storage Elastic Modulus)

A shear storage elastic modulus at −30° C. (G′(−30° C.)) of the present adhesive sheet obtained by dynamic viscoelasticity measurement with a shear mode at a frequency of 1 Hz is preferably not greater than 1200 kPa, more preferably not greater than 1000 kPa, further preferably not greater than 800 kPa, particularly preferably not greater than 700 kPa, still particularly preferably not greater than 500 kPa, still further preferably not greater than 400 kPa, still furthermore preferably not greater than 300 kPa, and still particularly furthermore preferably not greater than 200 kPa.

A lower limit of the shear storage elastic modulus (G′(−30° C.)) of the present adhesive sheet is preferably not less than 100 kPa in terms of balance with the shear storage elastic modulus at high temperature.

The shear storage elastic modulus (G′(−30° C.)) of the present adhesive sheet within the above range can reduce interlayer stress with folding of a laminate or a laminate for an image display device at particularly low temperature to high temperature when the present adhesive sheet is adhered to, for example, a member sheet to form the laminate or the laminate for an image display device, which can inhibit delamination and cracking of the member sheet or the flexible image display device constituent member.

A shear storage elastic modulus at −20° C. (G′(−20° C.)) of the present adhesive sheet obtained by dynamic viscoelasticity measurement with a shear mode at a frequency of 1 Hz is preferably not greater than 500 kPa, further preferably not greater than 400 kPa, particularly preferably not greater than 300 kPa, and furthermore preferably not greater than 250 kPa.

A lower limit of the shear storage elastic modulus (G′(−20° C.)) of the present adhesive sheet is preferably not less than 50 kPa in terms of balance with the shear storage elastic modulus at high temperature.

The shear storage elastic modulus (G′(−20° C.)) of the present adhesive sheet within the above range can reduce interlayer stress with folding of a laminate or a laminate for an image display device at particularly low temperature to high temperature when the present adhesive sheet is adhered to, for example, a member sheet to form the laminate or the laminate for an image display device, which can inhibit delamination and cracking of the member sheet or the flexible image display device constituent member.

A shear storage elastic modulus at 25° C. (G′(25° C.)) of the present adhesive sheet obtained by dynamic viscoelasticity measurement with a shear mode at a frequency of 1 Hz is preferably not greater than 100 kPa, further preferably not greater than 50 kPa, particularly preferably not greater than 40 kPa, and furthermore preferably not greater than 30 kPa from the viewpoint of yielding high adhesiveness.

A lower limit of the shear storage elastic modulus (G′(25° C.)) of the present adhesive sheet is preferably not less than 5 kPa from the viewpoints of preventing glue ooze and retaining the shape of the adhesive sheet.

A shear storage elastic modulus at 60° C. (G′(60° C.)) of the present adhesive sheet obtained by dynamic viscoelasticity measurement with a shear mode at a frequency of 1 Hz is preferably not greater than 50 kPa, further preferably not greater than 40 kPa, particularly preferably not greater than 35 kPa, and furthermore preferably not greater than 30 kPa from the viewpoint of yielding high adhesiveness.

A lower limit of the shear storage elastic modulus (G′(60° C.)) of the present adhesive sheet is preferably not less than 1 kPa from the viewpoints of preventing glue ooze and retaining the shape of the adhesive sheet.

A shear storage elastic modulus at 80° C. (G′(80° C.)) of the present adhesive sheet obtained by dynamic viscoelasticity measurement with a shear mode at a frequency of 1 Hz is preferably not greater than 50 kPa, further preferably not greater than 40 kPa, particularly preferably not greater than 35 kPa, and furthermore preferably not greater than 30 kPa from the viewpoint of yielding high adhesiveness.

A lower limit of the shear storage elastic modulus (G′(80° C.)) of the present adhesive sheet is preferably not less than 1 kPa, more preferably not less than 3 kPa, further preferably not less than 5 kPa, particularly preferably not less than 8 kPa, furthermore preferably not less than 11 kPa, and still particularly preferably not less than 15 kPa from the viewpoints of preventing glue ooze and retaining the shape of the adhesive sheet.

A shear storage elastic modulus ratio (G′(−30° C.)/G′ (80° C.)) of the present adhesive sheet between the shear storage elastic modulus at −30° C. (G′(−30° C.)) and the shear storage elastic modulus at 80° C. (G′(80° C.)) obtained by dynamic viscoelasticity measurement with a shear mode at a frequency of 1 Hz is 1 to 65, preferably 1 to 50, more preferably 2 to 35, particularly preferably 3 to 30, and still particularly preferably 4 to 20.

Since the present adhesive sheet has the shear storage elastic modulus ratio (G′(−30° C.)/G′ (80° C.)) within the above range, the present adhesive sheet exhibits excellent flexibleness. That is, the present adhesive sheet achieves both flexibility and cohesion, which can prevent both breakage of members in folding at low temperature and folding trace in folding at high temperature.

### (Maximum Point of Loss Tangent (Tan δ) and Glass Transition Temperature (Tg))

A maximum point of a loss tangent (tan δ) of the present adhesive sheet obtained by dynamic viscoelasticity measurement with a shear mode at a frequency of 1 Hz is preferably not higher than-20° C., further preferably not higher than −25° C., particularly preferably not higher than −30° C., still particularly preferably not higher than-35° C., and furthermore preferably not higher than −40° C. The lower limit is typically −80° C.

The maximum point of the loss tangent (tan δ) can be interpreted as a glass transition temperature (Tg). The glass transition temperature (Tg) within the above range easily regulates the shear storage elastic modulus (G′(−30° C.)) of the present adhesive sheet to be not greater than 1200 kPa.

When an inflection point of the loss tangent (tan δ) obtained by dynamic viscoelasticity measurement with a shear mode at a frequency of 1 Hz is observed at only one point, in other words, when the tan δ curve exhibits a single-peak shape, the glass transition temperature (Tg) can be regarded to be single.

The term “maximum point” in the loss tangent (tan δ) means a point having a maximum value within a predetermined range or an entire range in peak values, namely inflection points with change from positive (+) to negative (−) when differentiated on the tan õ curve.

The shear storage elastic modulus (G′) at each temperature and the loss tangent (tan δ) can be measured by using a rheometer.

The shear storage elastic modulus (G′) and the loss tangent (tan δ) can be regulated within the above ranges by regulating the adhesive composition to constitute the present adhesive sheet, the types, the weight-average molecular weight, etc. of the components contained in the syrup composition (for example, the aforementioned acrylic copolymer, radically polymerizable compound, etc.) or by further regulating a gel fraction, etc., of the adhesive sheet. The regulating method is not limited thereto.

### (Adhesive Force)

The adhesive force of the acrylic adhesive layer of the present adhesive sheet is appropriately decided according to the material of the adherent, etc. For example, when adhering to glass, polyethylene terephthalate (PET), polyimide (CPI), polycarbonate, polymethyl methacrylate, or ITO-layer-deposited PET, the adhesive sheet has an adhesive force of preferably 1 to 50 N/cm, particularly preferably 2 to 30 N/cm, and further preferably 5 to 20 N/cm. Specifically, the adhesive force can be measured by a method described in Examples described later.

### (Recovering Properties)

The present adhesive sheet has a recovering rate of preferably not less than 80%, and more preferably not less than 85%. The recovering rate is calculated with the present adhesive sheet having a thickness of 0.5 to 1.2 mm by the following formula from a strain after applying a pressure of 10 kPa at a temperature of 25° C. for 600 seconds (γₘₐₓ (25)) and a strain after 600 seconds from removing the stress (γₘᵢₙ (25)).

$$Recovering rate ( \% ) = [ ( {γ}_{max ( 25 )} - {γ}_{min ( 25 )} ) / {γ}_{max ( 25 )} ] \times 100$$

The present adhesive sheet has a recovering rate of preferably not less than 70%, and more preferably not less than 75%. The recovering rate is calculated with the present adhesive sheet having a thickness of 0.5 to 1.2 mm by the following formula from a strain after applying a pressure of 10 kPa at a temperature of −20° C. for 600 seconds (γₘₐₓ (−20)) and a strain after 600 seconds from removing the stress (γₘᵢₙ (−20)).

$$Recovering rate ( \% ) = [ ( {γ}_{max ( - 20 )} - {γ}_{min ( - 20 )} ) / {γ}_{max ( - 20 )} ] \times 100$$

The present adhesive sheet having such recovering properties has excellent flexibleness of not leaving a folding trace by placing in a bent state even when the present adhesive sheet adheres to a member sheet and is subjected to folding operations at low temperature or high temperature. Since higher recovering properties are more preferable, an upper limit of the recovering properties is 100%.

To improve flexibleness of the present adhesive sheet, a monofunctional radically polymerizable compound having an alkylene glycol skeleton is preferably used as the radically polymerizable compound (x), and the acrylic copolymer or the acrylic adhesive layer more preferably has the structural moiety derived from the hydroxy-group-containing (meth)acrylate.

In this case, the monofunctional radically polymerizable compound having an oxyalkylene structure having an alkylene group with a length within a certain range bonded to the acrylic copolymer strengthens entwining of the polymer chains, which increases a difference in entropy before and after stretching to improve the recovering properties with entropic elasticity.

Note that the method for regulating the recovering properties is not limited to these methods.

### (Gel Fraction)

A gel fraction of the present adhesive sheet is preferably 30 to 95 mass %, more preferably 50 to 90 mass %, further preferably 55 to 85 mass %, and particularly preferably 60 to 85 mass %. The gel fraction of the present adhesive sheet of not lower than the lower limit can sufficiently retain the shape, and the gel fraction of not greater than the upper limit can increase the adhesive force.

The gel fraction is an indicator of the degree of crosslinking (degree of curing), and can be measured under a measurement condition described in Examples described later.

### (Transparency and Haze)

The present adhesive sheet has transparency with visual observation, and the transparency indicates that the components are uniformly dissolved each other.

The present adhesive sheet has a haze of preferably not greater than 1.0%, further preferably not greater than 0.8%, and particularly preferably not greater than 0.5%.

The haze of the present adhesive sheet of not greater than 1.0% tends to be preferably usable for usage of image display devices.

To regulate the haze of the present adhesive sheet within the above range, the present adhesive sheet preferably contains no particle such as organic particles.

### (Thickness)

A thickness of the present adhesive sheet is not particularly limited. The thickness of not less than 10 μm yields good handling properties, and the thickness of not greater than 1000 μm can contribute to thinning of the present adhesive sheet.

Thus, the thickness of the present adhesive sheet is preferably not less than 10 μm, specifically not less than 15 μm, particularly not less than 20 μm, and further not less than 25 μm.

Meanwhile, the upper limit is preferably not greater than 1000 μm, specifically not greater than 500 μm, particularly not greater than 250 μm, further not greater than 100 μm, and still particularly not greater than 75 μm.

### <Preferable Usage of the Present Adhesive Sheet>

The present adhesive sheet is suitably used for adhering an image display device constituent member. Specifically, the present adhesive sheet is suitably used for adhering a member to constitute a display member (also referred to as “display member”), more specifically used for adhering a flexible image display device constituent member used for producing a display. The present adhesive sheet is used as an adhesive sheet for a constituent member of a flexible image display device.

As the flexible image display device constituent member, members same as those described later may be used.

### <<Laminate for Image Display Device>>

The laminate for an image display device according to an example of an embodiment of the present disclosure (hereinafter, which may be referred to as “the present laminate for an image display device”) is a laminate for an image display device having a configuration in which two constituent members of an image display device are laminated via the present adhesive sheet. The present laminate for an image display device is preferably a laminate for a flexible image display device having a configuration in which two constituent members for a flexible image display device are laminated via the present adhesive sheet (hereinafter, which may be referred to as “the present laminate for a flexible image display device”).

Among constituents of the present laminate for an image display device, the present adhesive sheet is as described above.

The constituents other than the adhesive sheet will be described below.

### (Constituent Member of Image Display Device)

Examples of the image display device constituent member to constitute the present laminate for an image display device include constituent members for a flexible image display device. Examples of the constituent member of a flexible image display device include flexible displays such as an organic electroluminescence (EL) display, a cover lens (cover film), a polarizing plate, a polarizer, a retardation film, a barrier film, a viewing-angle compensating film, a luminescence improving film, a contrast improving film, a diffusing film, a semitransparent reflective film, an electrode film, a transparent conductive film, a metal mesh film, and a touch sensor film. Two of any one or two of them are used in combination. Examples of the combination include: a combination of a flexible display and another constituent member of a flexible image display device; and a combination of a cover lens and another constituent member of a flexible image display device.

The constituent member of a flexible image display device means a bendable member, specifically a repeatedly bendable member. The flexible member is preferably a member fixable in a curved shape with a curvature radius of not less than 25 mm, and more preferably a member durable for repeated bending actions with a curvature radius of less than 25 mm, more preferably a curvature radium of less than 3 mm.

In the aforementioned configuration, examples of a main component in the constituent member of a flexible image display device include a resin sheet or glass.

Examples of a material of such a resin sheet include polyester resin, cycloolefin resin, triacetylcellulose resin, polymethyl methacrylate resin, polyurethane, epoxy resin, polyimide resin, and aramid resin. The material may be one resin or two or more resins. Among these, the resin sheet preferably contains, as a main component, at least one resin selected from the group consisting of polyester resin, cycloolefin resin, triacetylcellulose resin, polymethyl methacrylate resin, epoxy resin, polyimide resin, aramid resin, and polyurethane resin.

Here, “the main component” refers to a component accounting for the highest mass proportion in components constituting the constituent member of a flexible image display device. Specifically, the main component accounts for preferably not less than 50 mass %, further preferably not less than 55 mass %, and particularly preferably not less than 60 mass % in the resin composition (resin sheet) forming the constituent member of a flexible image display device.

The constituent member of a flexible image display device may be composed of thin-film glass.

In the aforementioned configuration, any one of the two constituent members of a flexible image display device, namely a first constituent member of a flexible image display device, preferably has a tensile strength at 25° C. measured in accordance with ASTM D882 of 10 to 900 MPa, particularly preferably 15 to 800 MPa, and further preferably 20 to 700 MPa.

The one constituent member of a flexible image display device preferably has a tensile strength at 25° C. (ASTM D882) within the above range because the flexible member hardly cracks even in bending.

The other constituent member of a flexible image display device, namely a second constituent member of a flexible image display device, preferably has a tensile strength at 25° C. measured in accordance with ASTM D882 of 10 to 900 MPa, particularly preferably 15 to 800 MPa, and further preferably 20 to 700 MPa.

The other constituent member of a flexible image display device preferably has a tensile strength at 25° C. (ASTM D882) within the above range because the flexible member hardly cracks even in bending.

Examples of the constituent member of a flexible image display device having a high tensile strength include a polyimide film, a polyester film, and an aramid film. The tensile strength of these films is typically not greater than 900 MPa.

On the other hand, examples of the constituent member of a flexible image display device having a rather low tensile strength include a triacetylcellulose (TAC) film and a cycloolefin polymer (COP) film. The tensile strength of these films is typically not less than 10 MPa.

The present laminate for a flexible image display device even with such a constituent member of a flexible image display device composed of the material having a rather low tensile strength can inhibit defects such as cracking by the action of the present adhesive sheet.

### <Method for Producing the Present Laminate for Image Display Device>

A method for producing the present laminate for an image display device is not particularly limited. For example, the adhesive composition may be applied on the image display device constituent member, preferably on the constituent member of a flexible image display device, to form the adhesive sheet as noted above, or the adhesive sheet may be formed in advance and then laminated to the image display device constituent member, preferably the constituent member of a flexible image display device.

### <<The Present Flexible Image Display Device>>

A flexible image display device according to an example of an embodiment of the present disclosure (hereinafter, which may be referred to as “the present flexible image display device”) is an image display device integrating the laminate for a flexible image display device having the configuration in which two constituent members of a flexible image display device are laminated via the present adhesive sheet. For example, the present flexible image display device having the laminate for a flexible image display device can be formed by laminating the laminated having the configuration in which two constituent members of a flexible image display device are laminated via the present adhesive sheet to another image display device constituent member.

The term “flexible image display device” refers to an image display device that leaves no folding trace even with repeated folding, that can quickly recover to the state before folding when releasing the folding, and that can display a strain-free image even in folding. More specific examples thereof include an image display device composed of a member fixable in a curved shape with a curvature radius of not less than 25 mm, and more preferably a member durable for repeated bending actions with a curvature radius of less than 25 mm, and more preferably a curvature radius of less than 3 mm.

The present laminate can prevent delamination and cracking of the laminate and has good recovering ability even with folding operation under an environment at high temperature. Therefore, it is one feature of the laminate that the flexible image display device having excellent flexibleness can be produced.

### <Adhesive Composition>

The adhesive composition according to an example of an embodiment of the present disclosure (hereinafter, referred to as “the present adhesive composition”) includes: an acrylic copolymer; and a radically polymerizable compound (x), wherein the acrylic copolymer has a weight-average molecular weight of not less than 500,000, the radically polymerizable compound (x) has a refractive index of less than 1.46, and the adhesive composition has a content of the radically polymerizable compound (x) of 20 to 95% in a total mass of the adhesive composition.

Hereinafter, each component contained in the present adhesive composition will be described in detail.

### Acrylic Copolymer

Examples of the acrylic copolymer include those same as the acrylic polymer described in the present adhesive sheet 1. Preferable types, contents, etc., of the monomer are also the same as above.

The weight-average molecular weight (Mw) of the acrylic copolymer is not less than 500,000, preferably not less than 550,000, and particularly preferably not less than 600,000 from the viewpoint of obtaining the adhesive composition having a high cohesion force.

An upper limit of the weight-average molecular weight (Mw) of the acrylic copolymer is preferably not greater than 1,500,000, more preferably not greater than 1,200,000, further preferably not greater than 1,100,000, and particularly preferably not greater than 1,000,000 in terms of operability and uniform stirring properties.

The glass transition temperature (Tg) of the acrylic copolymer is preferably not higher than −20° C., more preferably not higher than −23° C., further preferably not higher than −25° C., particularly preferably not higher than −30° C., and still particularly preferably not higher than −40° C. in terms of inhibition of increase in the shear storage elastic modulus (G′) at low temperature. With concern about glue ooze, etc., due to decrease in the shear storage elastic modulus at high temperature, the lower limit of the glass transition temperature (Tg) is typically −70° C., and preferably −50° C.

A content of the acrylic copolymer is typically 10 to 75%, preferably 12 to 73%, more preferably 20 to 71%, and particularly preferably 30 to 69% in the total mass of the adhesive composition.

### Radically Polymerizable Compound (x)

Examples of the radically polymerizable compound (x) include those same as the radically polymerizable compound (x) described in the present adhesive sheet 1. Preferable compounds, physical properties, etc., are same as of the radically polymerizable compound (x) described in the present adhesive sheet 1.

The radically polymerizable compound (x) has a refractive index of a monomer of less than 1.46, preferably not greater than 1.45, and particularly preferably not greater than 1.44 from the viewpoint of reducing the refractive index of the adhesive sheet composed of the present adhesive composition.

An acrylic copolymer typically has a refractive index of about 1.47. When an adhesive sheet is produced from an adhesive composition containing this acrylic copolymer, it is difficult to reduce the refractive index of the adhesive sheet to not greater than 1.470. In the present disclosure, use of the radically polymerizable compound (x) having a low refractive index can tend to reduce the refractive index of the adhesive sheet composed of the present adhesive composition.

The content of the radically polymerizable compound (x) is preferably 20 to 95%, more preferably 27 to 88%, more preferably 29 to 80%, and particularly preferably 31 to 70% in the total mass of the adhesive composition. Setting the content of the radically polymerizable compound (x) to be within the above range can reduce the refractive index of the adhesive sheet composed of the present adhesive composition, and can further provide excellent flexibleness.

The content of the radically polymerizable compound (x) is preferably 25 to 1900 parts by mass, more preferably 35 to 740 parts by mass, further preferably 40 to 400 parts by mass, and particularly preferably 45 to 240 parts by mass relative to 100 parts by mass of the acrylic copolymer. Setting the content of the radically polymerizable compound (x) to be within the above range can reduce the refractive index of the adhesive sheet composed of the present adhesive composition, and can further provide excellent flexibleness.

Further, the present adhesive composition preferably contains the photopolymerization initiator described in the aforementioned present adhesive sheet 1, and may contain the thermal crosslinker and the other components that are described in the aforementioned present adhesive sheet 1. Preferable types, contents, etc., of the photopolymerization initiator, the thermal crosslinker, and the other components are same as in the present adhesive sheet 1.

The present adhesive composition is prepared by mixing predetermined amounts of the acrylic copolymer, the radically polymerizable compound (x), preferably the photopolymerization initiator, and as necessary the thermal crosslinker and other components.

When the present adhesive composition is prepared, the raw materials are kneaded by using a temperature-controllable kneading apparatus (for example, a uniaxial extruder, a biaxial extruder, a planetary mixer, a biaxial mixer, and a pressurizing kneader).

When the raw materials are kneaded, the additives such as the silane-coupling agent and the oxidation inhibitor may be blended with the resin in advance and then supplied into the kneading apparatus, all the materials may be melt-mixed in advance and then supplied, or only the additives may be condensed into the resin in advance to produce a master batch and then supplied.

When the adhesive sheet is produced by using the present adhesive composition obtained as above, the adhesive sheet having a low refractive index and excellent flexibleness can be provided.

### EXAMPLES

Hereinafter, the present disclosure will be specifically described with Examples, but the present disclosure is not limited by the following Examples.

In Examples, “parts” means one on a mass basis.

The glass transition temperature and the weight-average molecular weight were measured in accordance with the aforementioned methods.

### <Production of Acrylic Copolymer>

Acrylic copolymers (1) to (7) were produced in accordance with a common method with copolymerization component composition as described in Table 1.

The following Table 1 also shows results of monomer composition (structural units derived from product components), the weight-average molecular weight, the glass transition temperature (Tg), and the refractive index of the obtained acrylic copolymers (1) to (7). Note that contents of the structural moieties derived from the product components (after polymerization) of the acrylic copolymer are approximately the same as composition of the copolymerization components.

TABLE 1

| | | | | | | | | | | Weight-average | Glass | |
|---|---|---|---|---|---|---|---|---|---|---|---|---|
| | | Copolymerization component (parts) | | | | | | | | molecular | transition | Refractive |
| | | 2EHA | BA | EA | MA | EMA | IBMA | 2HEA | 4HBA | weight | temperature | index |
| Acrylic | (1) | 67 | — | 10 | 5 | — | — | 14 | 4 | 700,000 | −23° C. | 1.473 |
| copolymer | (2) | 60 | — | 12.5 | 10 | — | — | 17.5 | — | 610,000 | −17° C. | 1.474 |
| | (3) | 60 | 15 | — | — | 5 | — | 20 | — | 770,000 | −23° C. | 1.473 |
| | (4) | 67 | — | 10 | 5 | — | — | 14 | 4 | 940,000 | −23° C. | 1.472 |
| | (5) | 39 | 39 | — | 4 | 6 | — | 12 | — | 700,000 | −19° C. | 1.472 |
| | (6) | 39 | 39 | — | 4 | — | 6 | 12 | — | 750,000 | −20° C. | 1.472 |
| | (7) | 38 | 38 | — | 4 | 4 | — | 16 | — | 900,000 | −20° C. | 1.474 |

2EHA: 2-Ethylhexyl acrylate,
BA: n-Butyl acrylate,
EA: Ethyl acrylate,
MA: Methyl acrylate,
EMA: Ethyl methacrylate,
IBMA: Isobutyl methacrylate,
2HEA: 2-Hydroxyethyl acrylate,
4HBA: 4-Hydroxybutyl acrylate

### <Radically Polymerizable Compound>

The following compound was prepared as the radically polymerizable compound.
Monofunctional urethane acrylate having oxypropylene structure (available from AGC Inc., refractive index: 1.450, weight-average molecular weight: about 10,000, glass transition temperature: −62° C.)

### <Photopolymerization Initiator>

Esacure TZT (available from IGM Resins B.V., mixture of 4-methylbenzophenone and 2,4,6-trimethylbenzophenone (hydrogen abstraction type))

### <Silane-Coupling Agent>

KBM 403 (available from Shin-Etsu Silicone, Co., Ltd., 3-glycidoxypropyltrimethoxysilane)

### Examples 1 to 10 and Comparative Examples 1 and 2

The acrylic copolymer, the radically polymerizable compound, the photopolymerization initiator, the silane-coupling agent, and ethyl acetate as a solvent were uniformly mixed with blending composition as described in the following Table 2 and Table 3 to obtain an adhesive composition solution (solid-content concentration: 33 mass %).

The adhesive composition solution was applied on a release film (produced by Mitsubishi Chemical Corporation, silicone-releasing-treated polyester film “MRV,” thickness: 100 μm) as a heavy-release film so that a thickness after drying was 50 μm. After the applying, the coating was placed in a drying apparatus heated to a temperature of 90° C. and retained for seven minutes to evaporate the solvent contained in the adhesive composition.

Further, formed on a surface of the solvent-dried adhesive composition was a laminate to which a release film as a light-release film (available from Mitsubishi Chemical Corporation, “MHE,” silicone-releasing-treated polyester film, thickness: 50 μm) was laminated. The adhesive composition was irradiated with UV through the release film by using a high-pressure mercury lamp (see Table 2 about each irradiation dose) to obtain an adhesive sheet laminate (adhesive sheet with release film).

The obtained adhesive sheet laminate was subjected to the following evaluation. The following Table 2 and Table 3 show the results.

### Refractive Index

The release films were removed from each of the adhesive sheet laminates produced in Examples and Comparative Examples, and the refractive index was determined by using an Abbe's refractometer (DR-A1-Plus) available from ATAGO CO., LTD. The refractive index was measured at 23° C. by using sodium D-line (589.3 nm).

### Glass Transition Temperature (Tg) and Shear Storage Elastic Modulus (G′)

The release film was removed from each of the adhesive sheet laminates produced in Examples and Comparative Examples, and a plurality of the adhesive sheets were laminated to form a laminate with 1.0 mm in thickness.

The obtained laminate of the adhesive sheets (adhesive layers) was punched to a cylinder with 8 mm in diameter (1.0 mm in height) to form a sample.

Temperature dispersion of dynamic viscoelasticity of the sample was measured under the following measurement conditions by using a viscoelasticity measurement apparatus (available from T. A. Instruments, trade name: “DHR 2”).

From the obtained temperature dispersion data of the dynamic viscoelasticity, read were a peak temperature of a loss tangent (tan δ) (glass transition temperature (Tg)) a shear storage elastic modulus G′ at −30° C. (−30° C.), a shear storage elastic modulus G′ at −20° C. (−20° C.), a shear storage elastic modulus G′ at 25° C. (25° C.), a shear storage elastic modulus G′ at 60° C. (60° C.), and a shear storage elastic modulus G′ at 80° C. (80° C.).

### (Measurement Condition)

Measurement tool: ϕ 8 mm parallel plate
Strain: 0.1%
Frequency: 1 Hz
Measurement temperature: −60 to 100° C.
Temperature raising rate: 5° C./min

### Adhesive Force

The light-release film was removed from each of the adhesive sheet laminates produced in Examples and Comparative Examples. On the adhesive surface of the adhesive sheet laminate, a polyethylene terephthalate film (available from Mitsubishi Chemical Corporation, DIAFOIL “S100,” thickness: 50 μm) as a lining film was rolling-laminated with a hand roller. This laminate was cut to a strip shape with 10 mm in width×150 mm in length, the remaining heavy-release film was peeled, and the exposed adhesive surface was rolling-laminated to glass by using a hand roller to produce a laminate composed of the glass/the adhesive sheet/the lining film. This laminate was left to stand under an environment at room temperature (23° C.) for overnight for aging to produce a sample for adhesive force measurement.

The lining film of each of the samples for adhesive force measurement was peeled while tensing with an angle of 180° formed with the glass at a peeling rate of 300 mm/min, and a tensile strength was measured with a load cell to measure a 180°-peeling strength (N/10-mm) of the adhesive sheet relative to the glass, which was specified as the adhesive force (23° C.).

### Recovering Properties

The release film was removed from each of the adhesive sheet laminates produced in Examples and Comparative Examples, and a plurality of the adhesive sheets were laminated to form a laminate with 1.0 mm in thickness.

The obtained laminate of the adhesive sheets (adhesive layers) was punched to a cylinder with 8 mm in diameter (1.0 mm in height) to form a sample.

The recovering properties of the sample were measured by using a viscoelasticity measurement apparatus (available from T. A. Instruments, “DHR 2”) under the following measurement condition.

That is, the recovering rate was calculated with a following formula from a strain (γₘₐₓ) after applying a pressure of 10 kPa for 600 seconds at 25° C. or −20° C. and a strain (γₘᵢₙ) after 600 seconds from subsequently removing a stress of the pressure.

$$Recovering rate ( \% ) = [ ( {γ}_{max} - {γ}_{min} ) / {γ}_{max} ] \times 100$$

### Gel Fraction

The release film was removed from each of the adhesive sheet laminates produced in Examples and Comparative Examples to form a sample.

The sample was wrapped with a 150-mesh SUS metal net and immersed in ethyl acetate for 24 hours. Thereafter, the sample was dried at 70° C. for 4.5 hours, masses of the adhesive before and after the immersion in ethyl acetate were each measured, and a difference between the mass was regarded as a [symbol] of an insoluble adhesive remained in the metal net. A mass percentage of the insoluble adhesive remained in the metal net relative to the mass of the adhesive before the immersion in ethyl acetate was calculated as a gel fraction (%) in a finally cured state.

TABLE 2

| | | | | Example 1 | Example 2 | Example 3 | Example 4 | Example 5 | Example 6 | Example 7 |
|---|---|---|---|---|---|---|---|---|---|---|
| Adhesive | Acrylic | (1) | parts | 100 | — | — | — | — | — | — |
| composition | copolymer | (2) | parts | — | 100 | — | — | — | — | — |
| | | (3) | parts | — | — | 100 | — | — | — | — |
| | | (4) | parts | — | — | — | 10 | 30 | 50 | 70 |
| | | (5) | parts | — | — | — | — | — | — | — |
| | | (6) | parts | — | — | — | — | — | — | — |
| | | (7) | parts | — | — | — | — | — | — | — |
| | Radically polymerizable | | parts¹⁾ | 50 | 50 | 75 | 100 | 100 | 100 | 100 |
| | compound (x) | | | | | | | | | |
| | Photopolymerization initiator | | parts¹⁾ | 4.5 | 3 | 2 | 3 | 3 | 3 | 3 |
| | Silane-coupling agent | | parts¹⁾ | 0.3 | 0.3 | 0.5 | 0.5 | 0.5 | 0.5 | 0.5 |
| | Content of radically | | % | 32 | 33 | 42 | 88 | 75 | 65 | 58 |
| | polymerizable compound | | | | | | | | | |
| Adhesive | Thickness | | μm | 50 | 50 | 50 | 50 | 50 | 50 | 50 |
| sheet | Integrated light | | J/cm² | 1 | 1 | 1 | 0.75 | 0.75 | 0.75 | 0.75 |
| | quantity | | | | | | | | | |
| | Refractive index | | — | 1.468 | 1.467 | 1.465 | 1.457 | 1.460 | 1.461 | 1.462 |
| | Glass transition temperature | | | −43 | −40 | −47 | −62 | −62 | −59 | −54 |
| | (Tg) | | | | | | | | | |
| | Storage shearing | −30° C. | kPa | 373 | 528 | 293 | 128 | 144 | 145 | 194 |
| | adhesive force (G′) | −20° C. | kPa | 167 | 213 | 140 | 63 | 69 | 73 | 89 |
| | | 25° C. | kPa | 30 | 31 | 34 | 27 | 24 | 24 | 25 |
| | | 60° C. | kPa | 17 | 15 | 22 | 27 | 21 | 19 | 19 |
| | | 80° C. | kPa | 13 | 11 | 20 | 28 | 21 | 19 | 18 |

¹⁾Blending amount relative to 100 parts of the acrylic copolymer

TABLE 3

| | | | | Example | Example | Example | Comparative | Comparative |
|---|---|---|---|---|---|---|---|---|
| | | | | 8 | 9 | 10 | Example 1 | Example 2 |
| Adhesive | Acrylic | (1) | parts | — | — | — | 100 | — |
| composition | copolymer | (2) | parts | — | — | — | — | — |
| | | (3) | parts | — | — | — | — | — |
| | | (4) | parts | 80 | — | — | — | — |
| | | (5) | parts | — | 100 | — | — | — |
| | | (6) | parts | — | — | 100 | — | — |
| | | (7) | parts | — | — | — | — | 100 |
| | Radically polymerizable | | parts¹⁾ | 100 | 25 | 25 | 25 | 25 |
| | compound (x) | | | | | | | |
| | Photopolymerization initiator | | parts¹⁾ | 2 | 3 | 3 | 3 | 3 |
| | Silane-coupling agent | | parts¹⁾ | 0.5 | — | — | 0.3 | — |
| | Content of radically | | % | 55 | 20 | 20 | 19 | 20 |
| | polymerizable compound | | | | | | | |
| Adhesive | Thickness | | μm | 50 | 50 | 50 | 50 | 50 |
| sheet | Integrated light | | J/cm² | 0.75 | 1 | 1 | 1 | 1 |
| | quantity | | | | | | | |
| | Refractive index | | — | 1.462 | 1.470 | 1.470 | 1.471 | 1.472 |
| | Glass transition temperature | | | −52 | −37 | −36 | −37 | −34 |
| | (Tg) | | | | | | | |
| | Storage shearing | −30° C. | kPa | 186 | 924 | 959 | 756 | 1309 |
| | adhesive force (G′) | −20° C. | kPa | 86 | 333 | 327 | 256 | 406 |
| | | 25° C. | kPa | 23 | 73 | 70 | 33 | 73 |
| | | 60° C. | kPa | 17 | 43 | 41 | 15 | 46 |
| | | 80° C. | kPa | 15 | 33 | 32 | 11 | 37 |

¹⁾Blending amount relative to 100 parts of the acrylic copolymer

### Reference Examples 1 to 3

The light-release film in the adhesive sheet laminate of Example 3 was changed to the following release films to produce adhesive sheet laminates (adhesive sheets with release film).
Reference Example 1: “MRQ,” available from Mitsubishi Chemical Corporation, silicone-releasing-treated polyester film, thickness: 50 μm
Reference Example 2: “MRV,” available from Mitsubishi Chemical Corporation, silicone-releasing-treated polyester film, thickness: 75 μm
Reference Example 3: “AS+8000A1-3g,” available from Zhongxing New Material Technology Co., Ltd., silicone-releasing-treated polyester film, thickness: 50 μm

The obtained adhesive sheet laminates of Reference Examples 1 to 3 and Example 3 were subjected to the following evaluation. The following Table 4 shows the results.

### Releasing Force of Release Film

A double-sided adhesive tape (available from Nitto Denko Corporation “No. 5000NS”) was rolling-laminated to a glass plate with a hand roller to prepare a glass with an adhesive tape.

The adhesive sheet laminates of Example 3 and Reference Examples 1 to 3 were cut to a strip shape with 50 mm in width×150 mm in length. The heavy-release film side of the cut adhesive sheet laminate was rolling-laminated to the adhesive tape surface of the glass with an adhesive tape by using a hand roller to produce a laminate composed of the glass/the adhesive sheet/the heavy-release film/the adhesive sheet/the light-release film (sample for releasing force measurement).

The light-release film of each of the samples for releasing force measurement was peeled under an environment at 23° C. while tensing with an angle of 180° formed with the adhesive sheet at a peeling rate of 300 mm/min, and a tensile strength was measured with a load cell to measure a 180°-peeling strength (N/cm) of the light-release film relative to the adhesive sheet, which was specified as the releasing force of the release film.

### Fluorescent X-Ray Analysis

As for the adhesive sheet laminates of Example 3 and Reference Examples 1 to 3, a peak intensity of Si atom on the adhesive surface exposed by peeling the light-release film was measured by using a fluorescent X-ray analyzer (available from Hitachi High-Tech Science Corporation, XRF device “EA1200VX”). The condition of the fluorescent X-ray analysis was as follows.
X-ray bulb: Rh target
Analysis mode: Qualification analysis
Tubular current/Tubular voltage: Auto/15 kV.
Measurement time: 100 seconds.
Collimator: φ 8.0 mm

### Bending Reliability Test

As for the adhesive sheet laminates of Example 3 and Reference Examples 1 to 3, a polarizing plate with 80 μm in thickness as a first member was rolling-laminated with a hand roller to the adhesive surface exposed by peeling the light-release film. A CPI film (available from Kolon Industries, Inc., “C_50,” thickness: 50 μm) as a second member was rolling-laminated with a hand roller to the adhesive surface exposed by peeling the remaining heavy-release film. Then, the laminate was left to stand under an environment at room temperature (23° C.) for overnight for aging to produce a sample for bending reliability test composed of the polarizing plate/the adhesive sheet/CPI.

The produced sample for bending reliability test was subjected to a U-shape bending cycle test with the CPI film side being an inner side and with setting of a curvature radius R=3 mm, 60 rpm (1 Hz), at a temperature of 60° C. and a relative humidity of 90% by using a durable system in a thermostatic and humidistatic chamber and using a face-shape unloaded U-shape expansion tester (available from Yuasa System Co., Ltd.). The number of cycles was 100,000.

The sample after the evaluation was visually evaluated with the following evaluation criteria.

### Evaluation Criteria

Very good: None of peeling, breakage, buckling, or floating occurred at a bending portion.

Poor: Any of peeling, breakage, buckling, or floating occurred at a bending portion.

TABLE 4

| | | | Reference | Reference | Reference |
|---|---|---|---|---|---|
| | Unit | Example 3 | Example 1 | Example 2 | Example 3 |
| Releasing force of | N/cm | 0.018 | 0.013 | 0.051 | 0.009 |
| release film | | | | | |
| Fluorescent X-ray | cps | 43 | 39 | 51 | 106 |
| analysis | | | | | |
| Bending | — | Very good | Very good | Very good | Poor |
| reliability test | | | | | |

The adhesive sheets of Examples 1 to 10 had a refractive index of not greater than 1.470. In addition, since the shear storage elastic modulus ratio between the shear storage elastic modulus at −30° C. and the shear storage elastic modulus at 80° C. was within the specific range, the adhesive sheets of Examples 1 to 10 exhibited low shear storage elastic moduli at −30 to 80° C., excellent recovering rates at 25° C. and −20° C., and excellent flexibleness.

Meanwhile, the adhesive sheets of Comparative Examples 1 and 2 had a high refractive index of greater than 1.470. In addition, since the shear storage elastic modulus ratio between the shear storage elastic modulus at −30° C. and the shear storage elastic modulus at 80° C. was out of the specific range, the adhesive sheets of Comparative Examples 1 and 2 exhibited a low recovering rate at −20° C. and poor recovering properties in folding. The adhesive sheet of Comparative Example 2 had a high refractive index of greater than 1.470. In addition, the storage elastic modulus at −30° C. was high, and the flexibleness was poor.

The adhesive sheets with a release film of Example 3 and Reference Examples 1 to 3 exhibited a small releasing force of the release film to provide good releasability from the adhesive sheet.

In addition, Example 3, Reference Example 1, and Reference Example 2, which used the release film with reduced transfer of the releasing agent toward the adhesive sheet, exhibited excellent reliability in the folding test.

Meanwhile, the adhesive sheet with a release film of Reference Example 3 exhibited a high peak intensity of Si atom in the fluorescent X-ray analysis on the adhesive sheet surface, and it was suggested that a large amount of the releasing agent component derived from the release film was transferred toward the adhesive sheet surface. Thus, peeling occurred in the reliability test on the interface between the first member and the adhesive sheet, resulting in deteriorated reliability.

The specific embodiments of the present disclosure have been described in the Examples, but the Examples are merely examples, and not limitedly interpreted. It is anticipated that various modifications obvious to a person skilled in the art are within the scope of the present disclosure.

### INDUSTRIAL APPLICABILITY

The adhesive sheet of the present disclosure has a low refractive index and has flexibleness, and is thereby useful as the adhesive sheet for obtaining various flexible image display devices such as bendable, foldable, rollable, and stretchable devices. Specifically, the adhesive sheet of the present disclosure is suitable for the adhesive sheet for a foldable image display device with repeated foldings.

1. An adhesive sheet formed with an adhesive composition comprising an acrylic copolymer and a radically polymerizable compound (x),
wherein the adhesive sheet has a refractive index of not greater than 1.470, and
wherein the adhesive sheet has a shear storage elastic modulus ratio (G′(−30° C.)/G′(80° C.)) of 1 to 65, the ratio being between a shear storage elastic modulus at −30° C. (G′(−30° C.)) and a shear storage elastic modulus at 80° C. (G′(80° C.)), and being obtained by dynamic viscoelasticity measurement with a shear mode at a frequency of 1 Hz.

2. The adhesive sheet according to claim 1, wherein the adhesive sheet has a content of the radically polymerizable compound (x) of 20 to 95% in a total mass of the adhesive composition.

3. The adhesive sheet according to claim 1, wherein the acrylic copolymer is an acrylic copolymer having: a structural moiety derived from a (meth)acrylate (a1) having an alkyl group having not less than 3 carbon atoms of the alkyl; and a structural moiety derived from a hydroxy-group-containing (meth)acrylate (a2).

4. The adhesive sheet according to claim 1, wherein the acrylic copolymer has a weight-average molecular weight of not less than 500,000.

5. An adhesive sheet, comprising an acrylic adhesive layer,
wherein the acrylic adhesive layer is a cured reaction product formed with a syrup composition comprising: an alkyl (meth)acrylate (a1) having not less than 3 carbon atoms of the alkyl group; a hydroxy-group-containing (meth)acrylate (a2); and a radically polymerizable compound (x),
wherein the adhesive sheet has a refractive index of not greater than 1.470, and
wherein the adhesive sheet has a shear storage elastic modulus ratio (G′(−30° C.)/G′ (80° C.)) of 1 to 65, the ratio being between a shear storage elastic modulus at −30° C. (G′(−30° C.)) and a shear storage elastic modulus at 80° C. (G′(80° C.)), and being obtained by dynamic viscoelasticity measurement with a shear mode at a frequency of 1 Hz.

6. The adhesive sheet according to claim 5, wherein the adhesive sheet has a content of a structural moiety derived from the radically polymerizable compound (x) of 20 to 95% in a total mass of the acrylic adhesive layer.

7. The adhesive sheet according to claim 1, wherein the radically polymerizable compound (x) has a refractive index of less than 1.46.

8. The adhesive sheet according to claim 1, wherein the radically polymerizable compound (x) has an alkylene glycol skeleton.

9. The adhesive sheet according to claim 1, wherein the radically polymerizable compound (x) has a urethane bond.

10. The adhesive sheet according to claim 1, wherein the shear storage elastic modulus at −30° C. (G′(−30° C.)) obtained by the dynamic viscoelasticity measurement with a shear mode at a frequency of 1 Hz is not greater than 1000 kPa.

11. The adhesive sheet according to claim 1, wherein the shear storage elastic modulus at 80° C. (G′(80° C.)) obtained by the dynamic viscoelasticity measurement with a shear mode at a frequency of 1 Hz is not less than 1 kPa.

12. The adhesive sheet according to claim 1, wherein the adhesive sheet has a glass transition temperature (Tg) of not higher than −20° C., the glass transition temperature being defined by a maximum value of Tan δ obtained with the dynamic viscoelasticity measurement with a shear mode at a frequency of 1 Hz.

13. The adhesive sheet according to claim 1, wherein the adhesive sheet has a recovering rate of not less than 80%, the recovering rate being calculated with a following formula from a strain (γₘₐₓ) after applying a pressure of 10 kPa for 600 seconds with a thickness of 0.5 to 1.2 mm at a temperature of 25° C. and a strain (γₘᵢₙ) after 600 seconds from subsequently removing a stress of the pressure,
the recovering rate (%)=[(γₘₐₓ−γₘᵢₙ)/γₘₐₓ]×100

14. The adhesive sheet according to claim 1, wherein the adhesive sheet has a gel fraction of 30 to 95 mass %.

15. An adhesive sheet with a release film, comprising:
the adhesive sheet according to claim 1; and
a release film laminated onto the adhesive sheet.

16. A laminate for an image display device, comprising:
two constituent members of an image display device; and
the adhesive sheet according to claim 1 interposed between the two constituent members of an image display device.

17. A flexible image display device, comprising the laminate for an image display device according to claim 16.

18. A constituent member of a flexible image display device, comprising the adhesive sheet according to claim 1.

19. An adhesive composition, comprising:
an acrylic copolymer; and
a radically polymerizable compound (x),
wherein the acrylic copolymer has a weight-average molecular weight of not less than 500,000,
wherein the radically polymerizable compound (x) has a refractive index of less than 1.46, and
wherein the adhesive composition has a content of the radically polymerizable compound (x) of 20 to 95% in a total mass of the adhesive composition.

20. The adhesive sheet according to claim 5, wherein the radically polymerizable compound (x) has a refractive index of less than 1.46.

21. The adhesive sheet according to claim 5, wherein the radically polymerizable compound (x) has an alkylene glycol skeleton.

22. The adhesive sheet according to claim 5, wherein the radically polymerizable compound (x) has a urethane bond.

23. The adhesive sheet according to claim 5, wherein the shear storage elastic modulus at −30° C. (G′(−30° C.)) obtained by the dynamic viscoelasticity measurement with a shear mode at a frequency of 1 Hz is not greater than 1000 kPa.

24. The adhesive sheet according to claim 5, wherein the shear storage elastic modulus at 80° C. (G′(80° C.)) obtained by the dynamic viscoelasticity measurement with a shear mode at a frequency of 1 Hz is not less than 1 kPa.

25. The adhesive sheet according to claim 5, wherein the adhesive sheet has a glass transition temperature (Tg) of not higher than −20° C., the glass transition temperature being defined by a maximum value of Tan δ obtained with the dynamic viscoelasticity measurement with a shear mode at a frequency of 1 Hz.

26. The adhesive sheet according to claim 5, wherein the adhesive sheet has a recovering rate of not less than 80%, the recovering rate being calculated with a following formula from a strain (γₘₐₓ) after applying a pressure of 10 kPa for 600 seconds with a thickness of 0.5 to 1.2 mm at a temperature of 25° C. and a strain (γₘᵢₙ) after 600 seconds from subsequently removing a stress of the pressure,
$$the recovering rate ( \% ) = [ ( {γ}_{max} - {γ}_{min} ) / {γ}_{max} ] \times 100$$

27. The adhesive sheet according to claim 5, wherein the adhesive sheet has a gel fraction of 30 to 95 mass %.

28. An adhesive sheet with a release film, comprising:
the adhesive sheet according to claim 5; and
a release film laminated onto the adhesive sheet.

29. A laminate for an image display device, comprising:
two constituent members of an image display device; and
the adhesive sheet according to claim 5 interposed between the two constituent members of an image display device.

30. A flexible image display device, comprising the laminate for an image display device according to claim 29.

31. An adhesive sheet for a constituent member of a flexible image display device, the adhesive sheet comprising the adhesive sheet according to claim 5.
